(19) United States
(12) Patent Application Publication
(10) Pub. No.: US 2018/0241008 A1
(43) Pub. Date: Aug. 23, 2018

(54) SELF-LIGHT EMITTING DISPLAY PANEL, AND DISPLAY DEVICE COMPRISING SAME

(71) Applicant: SAMSUNG ELECTRONICS CO., LTD., Suwon-si (KR)

(72) Inventors: Young Mo KANG, Seoul (KR); Jun-ho SUNG, Seoul (KR); Joo-won LEE, Suwon-si (KR)

(73) Assignee: SAMSUNG ELECTRONICS CO., LTD., Suwon-si (KR)

(21) Appl. No.: 15/753,681

(22) PCT Filed: Jul. 15, 2016
(86) PCT No.: PCT/KR2016/007711

§ 371 Date: Feb. 20, 2018

(30) Foreign Application Priority Data
Aug. 19, 2015 (KR) 10-2015-0116507

(51) Int. Cl. H01L 51/52; H01L 27/32

(52) U.S. Cl. CPC H01L 51/5284; H01L 27/3244

(57) ABSTRACT

Disclosed are a display panel and a display device, the display panel comprising: a substrate; a first electrode layer and a second electrode layer configured to face with each other in the substrate; a light emitting layer configured to be interposed between the first electrode layer and the second electrode layer, and emit light based on voltage applied to the first electrode layer and the second electrode layer; a polarization layer comprising a linear lattice configured to transmit a first polarized component of the light emitted from the light emitting layer, and reflect a second polarized component of the emitted light; a phase shift layer configured to shift a phase of the light of the second polarized component reflected from the polarization layer, and output the light of the first polarized component by shifting a phase of the light reflected from at least one of the first electrode layer and the second electrode layer; an absorption layer configured to be provided at a side where the light of the first polarized component of the polarization layer exits, transmit the light of the first polarized component from an outside, and absorb the light of the second polarized component from the outside; and a buffer layer configured to be provided at a side where the light of the first polarized component of the polarization layer exits, and absorb the light of the second polarized component from the outside.

### FIELD

The present invention relates to a display panel having a self-light emitting structure to display an image, and a display device including the same.

### BACKGROUND ART

A display device refers to a device that includes a display panel and displays a broadcast signal or an image signal/image data of various formats. The display device may be materialized by a TV, a monitor or the like. The display panel of various types such as a liquid crystal display panel, a plasma display panel, etc. according to its features is applied to various display devices and displays an input image signal as an image on an effective display area. The display panel provided in the display device is classified into a light-receiving panel structure and a self-emissive panel structure in accordance with how to generate light for displaying an image. In case of the light-receiving panel structure, the display panel cannot emit light in itself, and thus needs a separate backlight unit for generating and providing light to the display panel. For example, the liquid crystal display panel has the light-receiving panel structure. On the other hand, the self-emissive panel structure emits light in itself and does not need a separate backlight unit. For example, an organic light emitting diode (OLED) panel or a light emitting diode (LED) signage has the self-emissive panel structure. In particular, among the self-emissive panels, the OLED panel includes an anode, an organic light emitting layer, and a cathode. Since external light is reflected from the anode, the cathode and like metal electrode, there is a problem of decreasing contrast. To solve this, there is a method of using a transparent electrode such as indium tin oxide (ITO), but this method has a disadvantage of increasing production costs. As another solution, an anti-reflection film including a phase-difference film for shifting a phase of the external light by λ/4 and a polarization plate for filtering out predetermined polarized light may be employed. In this case, it is possible to solve the problem that the contrast is decreased by the reflection of the external light, but another problem arises in that an optical efficiency of the organic light emitting diode may drop below 50%. Such an additional problem occurs in not only the OLED panel but also the LED signage where a plurality of LEDs are arranged in the form of a matrix and the plurality of LEDs arranged in the matrix form are used as pixels for displaying an image. Therefore, if it is possible to both prevent reflection of external light by improving the absorptivity of the external light and enhance an optical efficiency of internal light from the OLED and the LED, the utility of the panel using the OLED and the LED will be further increased.

### DISCLOSURE

### Technical Problem

Accordingly, an object of the present invention is to provide a display panel capable of not only enhancing an optical efficiency of internal light but also improving absorptivity of external light to prevent reflection of the external light, and a display device including the same.

### Technical Solution

According to an aspect of an exemplary embodiment, a display panel comprising: a substrate; a first electrode layer and a second electrode layer configured to face with each other in the substrate; a light emitting layer configured to be interposed between the first electrode layer and the second electrode layer, and emit light based on voltage applied to the first electrode layer and the second electrode layer; a polarization layer comprising a linear lattice configured to transmit a first polarized component of the light emitted from the light emitting layer, and reflect a second polarized component of the emitted light; a phase shift layer configured to shift a phase of the light of the second polarized component reflected from the polarization layer, and output the light of the first polarized component by shifting a phase of the light reflected from at least one of the first electrode layer and the second electrode layer; an absorption layer configured to be provided at a side where the light of the first polarized component of the polarization layer exits, transmit the light of the first polarized component from an outside, and absorb the light of the second polarized component from the outside; and a buffer layer configured to be provided at a side where the light of the first polarized component of the polarization layer exits, and absorb the light of the second polarized component from the outside. Thus, the second polarized component of the internal light is recycled to enhance an optical efficiency, and the absorptivity of the second polarized component of the external light is improved to thereby make the display panel prevent the reflection of the external light.

Thickness of at least one of the absorption layer and the buffer layer has a value so that transmittance of the light of the first polarized component exiting to an outside can be equal to or higher than a first lower limit value, and absorptivity of the light of the second polarized component receiving from an outside can be equal to or higher than a second lower limit value. Thus, it is possible to provide the display panel including the absorption layer and the buffer layer, each thickness of which is optimized to the optical efficiency of the internal light and the absorptivity of the external light.

Thickness of the absorption layer is a value within a first range corresponding to a first lower limit value or higher of transmittance of the light, and thickness of the buffer layer is a value within a second range corresponding to a second lower limit value or higher of absorptivity of the light. Thus, it is possible to provide the display panel including the absorption layer and the buffer layer, each thickness range of which is optimized to the optical efficiency of the internal light and the absorptivity of the external light.

The buffer layer is interposed between the absorption layer and the polarization layer. Thus, it is possible to provide the display panel having a layered structure optimized to the optical efficiency of the internal light and the absorptivity of the external light.

The buffer layer is interposed between the substrate and the polarization layer. Thus, it is possible to provide the display panel having a layered structure optimized to the optical efficiency of the internal light and the absorptivity of the external light.

The buffer layer is stacked on the absorption layer. Thus, it is possible to provide the display panel having a layered structure optimized to the optical efficiency of the internal light and the absorptivity of the external light.

The polarization layer comprises a plurality of linear lattices arranged in a lattice form to transmit the light of the first polarized component. Thus, it is possible to provide the display panel that not only transmits the light of the first polarized component but also reflects and recycles the light of the second polarized component.

At least one of the absorption layer and the buffer layer is arranged in each of the plurality of linear lattices. Thus, it is possible to provide a thin display panel.

According to an aspect of another exemplary embodiment, a display device comprising: a signal receiver configured to receive an image signal; a signal processor configured to process the image signal received in the signal receiver; and a display panel configured to display the image signal processed by the signal processor, the display panel comprising: a substrate; a first electrode layer and a second electrode layer configured to face with each other in the substrate; a light emitting layer configured to be interposed between the first electrode layer and the second electrode layer, and emit light based on voltage applied to the first electrode layer and the second electrode layer; a polarization layer comprising a linear lattice configured to transmit a first polarized component of the light emitted from the light emitting layer, and reflect a second polarized component of the emitted light; a phase shift layer configured to shift a phase of the light of the second polarized component reflected from the polarization layer, and output the light of the first polarized component by shifting a phase of the light reflected from at least one of the first electrode layer and the second electrode layer; an absorption layer configured to be provided at a side where the light of the first polarized component of the polarization layer exits, transmit the light of the first polarized component from an outside, and absorb the light of the second polarized component from the outside; and a buffer layer configured to be provided at a side where the light of the first polarized component of the polarization layer exits, and absorb the light of the second polarized component from the outside. Thus, the second polarized component of the internal light is recycled to enhance an optical efficiency, and the absorptivity of the second polarized component of the external light is improved to thereby make the display panel prevent the reflection of the external light.

Thickness of at least one of the absorption layer and the buffer layer has a value so that transmittance of the light of the first polarized component exiting to an outside can be equal to or higher than a first lower limit value, and absorptivity of the light of the second polarized component receiving from an outside can be equal to or higher than a second lower limit value. Thus, it is possible to provide the display panel including the absorption layer and the buffer layer, each thickness of which is optimized to the optical efficiency of the internal light and the absorptivity of the external light.

Thickness of the absorption layer is a value within a first range corresponding to a first lower limit value or higher of transmittance of the light, and thickness of the buffer layer is a value within a second range corresponding to a second lower limit value or higher of absorptivity of the light. Thus, it is possible to provide the display panel including the absorption layer and the buffer layer, each thickness range of which is optimized to the optical efficiency of the internal light and the absorptivity of the external light.

The buffer layer is interposed between the absorption layer and the polarization layer. Thus, it is possible to provide the display panel having a layered structure optimized to the optical efficiency of the internal light and the absorptivity of the external light.

The buffer layer is interposed between the substrate and the polarization layer. Thus, it is possible to provide the display panel having a layered structure optimized to the optical efficiency of the internal light and the absorptivity of the external light.

The buffer layer is stacked on the absorption layer. Thus, it is possible to provide the display panel having a layered structure optimized to the optical efficiency of the internal light and the absorptivity of the external light.

The polarization layer comprises a plurality of linear lattices arranged in a lattice form to transmit the light of the first polarized component, and at least one of the absorption layer and the buffer layer is arranged in each of the plurality of linear lattices. Thus, it is possible to provide the display panel that not only transmits the light of the first polarized component but also reflects and recycles the light of the second polarized component, and has a thin thickness.

### Advantageous Effects

According to the present invention, there are provided a display panel capable of not only enhancing an optical efficiency of internal light but also improving absorptivity of external light to prevent reflection of the external light, and a display device including the same.

### DESCRIPTION OF DRAWINGS

FIG. 1 is a block diagram of a display device according to one embodiment of the present invention,

FIG. 2 is a lateral cross-section view of schematically showing a layered structure of a display panel according to one embodiment of the present invention,

FIG. 3 is a lateral cross-section view of schematically showing a layered structure of a display panel according to one embodiment of the present invention,

FIG. 4 illustrates an example for describing processes in which polarization properties of external light incident upon the display panel of FIG. 2 are changed step by step,

FIG. 5 illustrates an example for describing processes in which polarization properties of light emitted from the display panel of FIG. 2 are changed step by step,

FIG. 6 is a lateral cross-section view of schematically showing a layered structure of a display panel according to one embodiment of the present invention,

FIG. 7 is a partial perspective view of illustrating a polarization layer in the display panel of FIG. 6,

FIG. 8 and FIG. 9 are lateral cross-section views of showing examples of polarization layers in the display panel of FIG. 6,

FIG. 10 illustrates an example for describing processes in which polarization properties of light emitted from the display panel of FIG. 6 are changed step by step,

FIG. 11 is a flowchart for describing processes in which polarization properties of light emitted from the display panel of FIG. 6 are changed step by step,

FIG. 12 is a lateral cross-section view of schematically showing a layered structure of a display panel according to one embodiment of the present invention,

FIG. 13 illustrates an example for describing processes in which polarization properties of light emitted from the display panel of FIG. 12 are changed step by step,

FIG. 14 illustrates an example for describing processes in which polarization properties of external light incident upon the display panel of FIG. 12 are changed step by step,

FIG. 15 is a flowchart for describing processes in which polarization properties of external light incident upon the display panel of FIG. 12 are changed step by step,

FIG. 16 is a lateral cross-section view of schematically showing a layered structure of a display panel according to one embodiment of the present invention,

FIG. 17 is a lateral cross-section view of an absorption polarization layer in the display panel of FIG. 16,

FIG. 18 illustrates an example for describing processes in which polarization properties of light emitted from the display panel of FIG. 16 are changed step by step,

FIG. 19 is a flowchart for describing processes in which polarization properties of light emitted from the display panel of FIG. 16 are changed step by step,

FIG. 20 illustrates an example for describing processes in which polarization properties of external light incident upon the display panel of FIG. 16 are changed step by step,

FIG. 21 is a lateral cross-section view of schematically showing a layered structure of a display panel according to one embodiment of the present invention,

FIG. 22 is a lateral cross-section view of showing an example of a polarization layer in the display panel of FIG. 21,

FIG. 23 is a lateral cross-section view of schematically showing a layered structure of a display panel according to one embodiment of the present invention,

FIG. 24 is a lateral cross-section view of schematically showing a layered structure of a display panel according to one embodiment of the present invention,

FIG. 25 and FIG. 26 are lateral cross-section view of an absorption polarization layer in the display panel of FIG. 24,

FIG. 27 is a lateral cross-section view of schematically showing a layered structure of a display panel according to one embodiment of the present invention,

FIG. 28 is a lateral cross-section view of schematically showing a layered structure of a display panel according to one embodiment of the present invention,

FIG. 29 is a lateral cross-section view of schematically showing a layered structure of a display panel according to one embodiment of the present invention,

FIG. 30 is a lateral cross-section view of schematically showing a layered structure of a display panel according to one embodiment of the present invention,

FIG. 31 is a lateral cross-section view of schematically showing a layered structure of a display panel according to one embodiment of the present invention,

FIG. 32 is a lateral cross-section view of schematically showing a layered structure of a display panel according to one embodiment of the present invention,

FIG. 33 is a lateral cross-section view of schematically showing a layered structure of a display panel according to one embodiment of the present invention,

FIG. 34 is a lateral cross-section view of schematically showing a layered structure of a display panel according to one embodiment of the present invention,

FIG. 35 is a lateral cross-section view of showing an example of a buffer polarization layer in the display panel of FIG. 34,

FIG. 36 is a graph of showing reflectivity of light of a second polarized component in accordance with change in thickness of an absorption layer and a buffer layer in the buffer polarization layer of FIG. 34,

FIG. 37 is a graph of showing transmittance of light of a first polarized component in accordance with change in thickness of the absorption layer and the buffer layer in the buffer polarization layer of FIG. 34,

FIG. 38 is a perspective view of a polarization layer of a display panel according to one embodiment of the present invention,

FIG. 39 is a perspective view of showing an example of a display panel according to one embodiment of the present invention,

FIG. 40 is a lateral cross-section view of schematically showing a layered structure of a display panel according to one embodiment of the present invention,

FIG. 41 is a lateral cross-section view of schematically showing a layered structure of a display panel according to one embodiment of the present invention, and

FIG. 42 is a lateral cross-section view of schematically showing a layered structure of a display panel according to one embodiment of the present invention.

### DETAILED DESCRIPTION

Below, embodiments of the present invention will be described with reference to accompanying drawings.

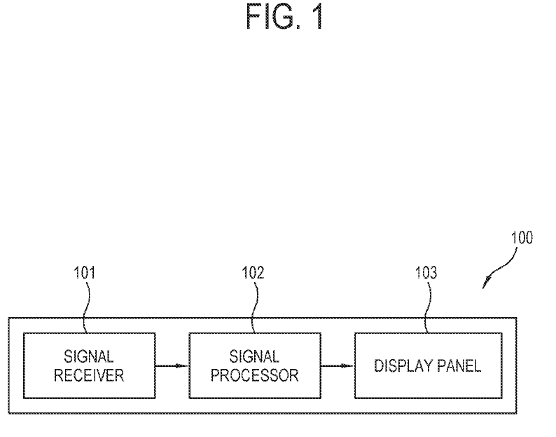

FIG. 1 is a block diagram of a display device 100 according to one embodiment of the present invention. As shown in FIG. 1, the display device 100 includes a signal receiver 101 to receive an image signal, a signal processor 102 to process the image signal received in the signal receiver 101 in accordance with preset image processing processes, and a display panel 103 to display an image based on the image signal processed by the signal processor 102. In this embodiment, the display device 100 is materialized as a TV. However, the display device 100 according to the present inventive concept is not limited to the TV, but the present inventive concept may be applied to any device capable of displaying an image based on an image signal/image data received from the outside or stored therein, for example, a monitor, a portable multimedia player, a mobile phone, and the like various display devices 100.

The signal receiver 101 receives and transmits an image signal/image data to the signal processor 102. The signal receiver 101 may be variously achieved in accordance with the formats of the received image signal and the types of the display device 100. For example, the signal receiver 101 may receive a radio frequency (RF) signal from a broadcasting station (not shown), or may receive an image signal of composite video, component video, super video, SCART, high definition multimedia interface (HDMI), DisplayPort, a unified display interface (UDI) or wireless HD standards. When the image signal is a broadcast signal, the signal receiver 101 includes a tuner (not shown) to be tuned to a channel corresponding to this broadcast signal. Alternatively, the signal receiver 101 may receive an image data packet from a server (not shown) through a network. The signal processor 102 performs various image processing processes to the image signal received in the signal receiver 101. The signal processor 102 outputs the image signal subjected to such processes to the display panel 103. The display panel 103 displays an image based on the image signal received from the signal processor 102. In this embodiment, the display panel 103 includes a self-emissive panel structure unlike a non-emissive panel structure such as a LCD panel. For example, the display panel 103 includes an organic light emitting diode (OLED) panel or a light emitting diode (LED) panel.

Hereinafter, terms ‘top/above’ and ‘bottom/below’ are to represent a relative arrangement or stack relationship between elements along a traveling direction of an exit light emitted from the display panel 103.

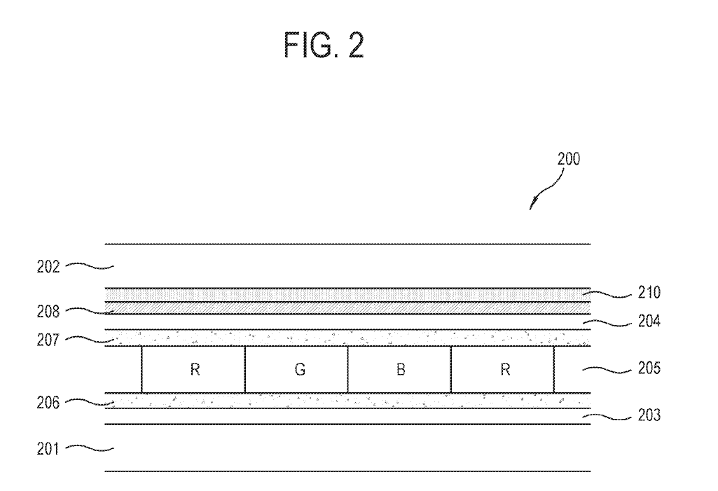

Below, referring to FIG. 2, a structure of a display panel 200 according to one embodiment of the present invention will be described. FIG. 2 is a lateral cross-section view of schematically showing a layered structure of the display panel 200 according to one embodiment of the present invention. As shown in FIG. 2, the display panel 200 includes a first substrate 201, a second substrate 202 arranged to face the first substrate 201, a first electrode layer 203, a second electrode layer 204 arranged to face the first electrode layer 203, a light emitting layer 205 interposed between the first electrode layer 203 and the second electrode layer 204, an electron transport layer 206 interposed between the first electrode layer 203 and the light emitting layer 205, a hole transport layer 207 interposed between the light emitting layer 205 and the second electrode layer 204, a phase shift layer 208 interposed between the second substrate 202 and the second electrode layer 204, and an absorption layer 210 interposed between the second substrate 202 and the phase shift layer 208. The first electrode layer 203 and the second electrode layer 204 respectively serve as a cathode and an anode. When negative (−) and positive (+) voltages are respectively applied to the first electrode layer 203 and the second electrode layer 204, electrons are generated in the cathode, i.e. the first electrode layer 203, and holes are generated in the anode, i.e. the second electrode layer 204. The electron transport layer 206 transports the electrons generated in the first electrode layer 203 to the light emitting layer 205, and the hole transport layer 207 transports the holes generated in the second electrode layer 204 to the light emitting layer 205. Like this, the electrons and holes transported to the light emitting layer 205 are combined to generate an exciton in the light emitting layer 205. The exciton refers to a neutral particle that is freely movable within a nonmetallic crystal as a unit of combined bodies between the electrons and the holes. The light emitting layer 205 emits light when the exciton falls from an excited state to a ground state, in which the light is generated in proportion to an electric current flowing from the anode, i.e. the second electrode layer 204 to the cathode, i.e. the first electrode layer 203. In the OLED panel structure, there are roughly two methods of generating light in the light emitting layer. One is that the light emitting layer generates white light and a color filter layer for converting the white light into light of red, green and blue (RGB) colors is provided above the light emitting layer. The other one is that the light emitting layer is divided in units of subpixels respectively generating light of RGB colors. In the latter case, there are no needs of a separate color filter layer since light of colors is emitted from the light emitting layer. In this embodiment, the light emitting layer 205 is configured to emit light of RGB colors, and thus a separate color filter layer is not applied to the display panel 200. The absorption layer 210 transmits a first polarized component of the light incident upon the display panel 200, but absorbs a second polarized component. The phase shift layer 208 converts the first polarized component transmitted through the absorption layer into the second polarized component to be absorbed in the absorption layer 210. Thus, it is possible to prevent contrast from being decreased by the reflection of the external light incident up on the display panel 200.

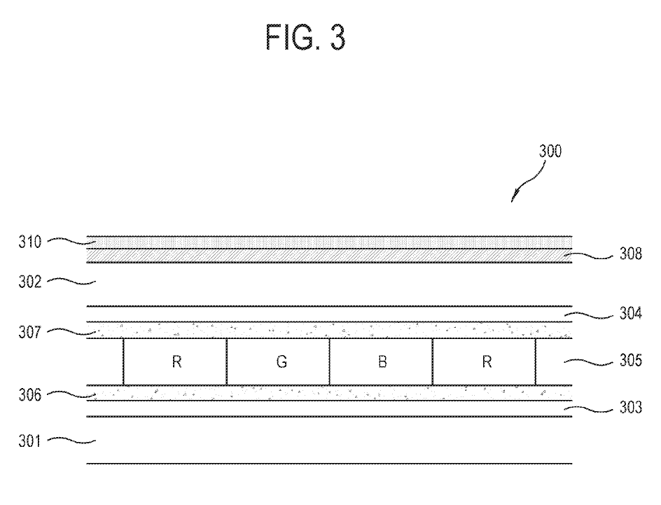

FIG. 3 shows a display panel 300 according to one embodiment of the present invention, which has the same structure as the display panel 200 of FIG. 2 except that a phase shift layer 308 and an absorption layer 310 are sequentially stacked on a top of a second substrate 302 of the display panel 300. Therefore, the display panel 300 also includes the absorption layer 310 and the phase shift layer 308, thereby preventing reflection of external light for the same reason as that of the display panel 200.

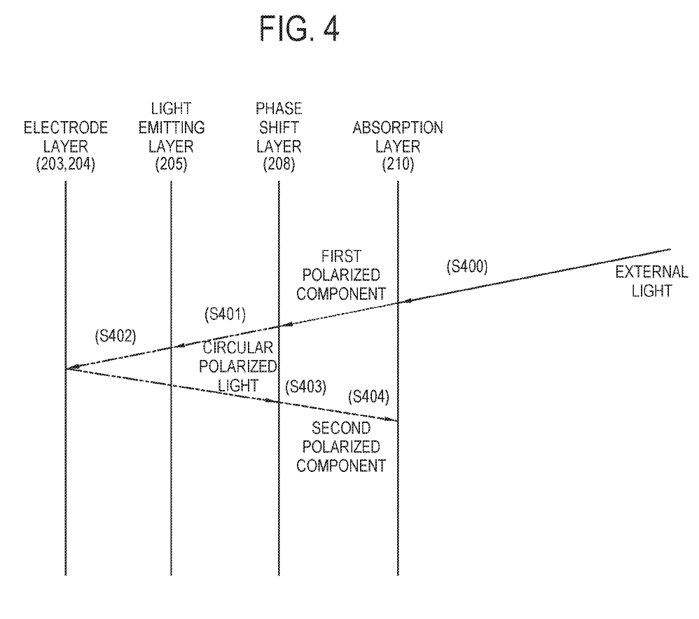

Below, referring to FIG. 4, it will be described in detail that the polarization properties of the external light incident upon the display panels 200 and 300 of FIG. 2 and FIG. 3 are changed step by step. The absorption layers 210 and 310 of the display panels 200 ad 300 shown in FIG. 2 and FIG. 3 are configured to transmit predetermined polarized light (hereinafter, referred to as a “first polarized component”) of non-polarized external light, but absorb different predetermined polarized light (hereinafter, referred to as a “second polarized component”) (S400). The light of the first polarized component transmitted through the absorption layers 210 and 310 is changed into light of circular polarized light, while passing through the phase shift layers 208 and 308 for shifting a phase by 1/λ (where, “λ” is a wavelength) (S401). Since the first electrode layers 203 and 303 and the second electrode layers 204 and 304 are made of metal, the circular polarized light is reflected from at least one of the first electrode layer 203, 303 and the second electrode layer 204, 304 (S402). The reflected circular polarized light is changed into light of the second polarized component, while passing through the phase shift layer 208, 308 (S403). Further, since the light of the second polarized component is absorbed in the absorption layer 210, 310, the display panel 200, 300 including the absorption layer 210, 310 and the phase shift layer 208, 308 can prevent the reflection of the external light and thus prevent the contrast from being decreased. However, the absorption layer 210, 310 capable of absorbing the light of the second polarized component not only decreases the contrast due to the reflection of the external light absorbs the light of the second polarized component, but also absorbs a second polarized component of light emitted from the light emitting layer 205, 305 (hereinafter, referred to as “internal light”), thereby causing a problem of lowering an optical efficiency with regard to even the internal light of the display panel 200, 300.

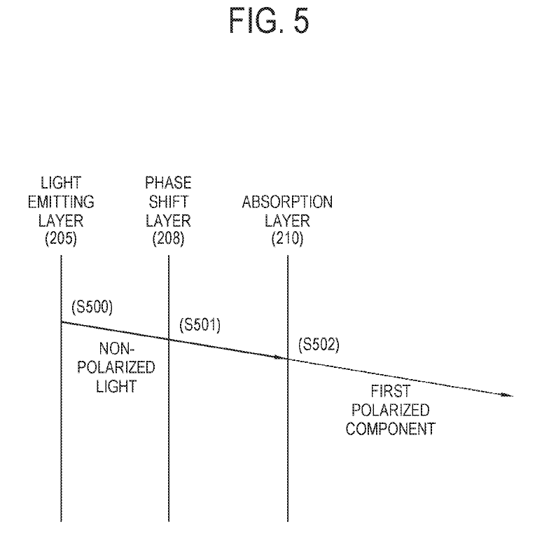

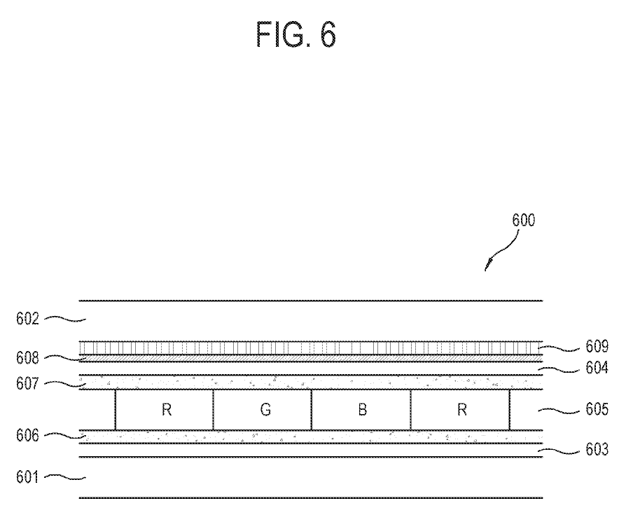

Below, referring to FIG. 5, it will be described in detail that the internal light of the display panel 200, 300 is decreased in the optical efficiency the absorption layer 210, 310. FIG. 5 illustrates an example for describing processes in which polarization properties of the internal light of the display panel 200 of FIG. 2 are changed step by step. The light emitting layer 205 of the display panel 200 emits non-polarized light (S500). The non-polarized light is not changed in polarization properties even though it passes through the phase shift layer 208 (S501). The absorption layer 210 transmits the light of the first polarized component of the non-polarized light passed through the phase shift layer 208, but absorbs the light of the second polarized component (S502). Therefore, a problem arises in that the optical efficiency of the light emitting layer 205 drops to about 50% as much as the absorbed light of the second polarized component. That is, the use of the absorption layer 210 for preventing the contrast from being decreased due to the reflection of the external light causes rather a problem of lowering the optical efficiency of the internal light. To solve this problem, there may be proposed a display panel shown in FIG. 6.

FIG. 6 is a lateral cross-section view of schematically showing a layered structure of a display panel 600 according to one embodiment of the present invention. As shown in FIG. 6, the display panel 600 includes a first substrate 601, a second substrate 602 arranged to face a first substrate 601, a first electrode layer 603, a second electrode layer 604 arranged to face the first electrode layer 603, a light emitting layer 605 interposed between the first electrode layer 603 and the second electrode layer 604, an electron transport layer 606 interposed between the first electrode layer 603 and the light emitting layer 605, and a hole transport layer 607 interposed between the light emitting layer 605 and the second electrode layer 604. These elements have the same functions as those of the display panel 200 shown in FIG. 2. In addition, the display panel 600 further includes a polarization layer 609 interposed between the second substrate 602 and a phase shift layer 608. The polarization layer 609 includes a plurality of linear lattices extended in parallel in one direction on the bottom of the second substrate 602. Herein, the bottom of the second substrate 602 refers to a surface of the second substrate 602 facing the second electrode layer 604. The linear lattices of the polarization layer 609 are arranged in parallel with each other, having preset thickness, width and pitches toward the second electrode layer 604.

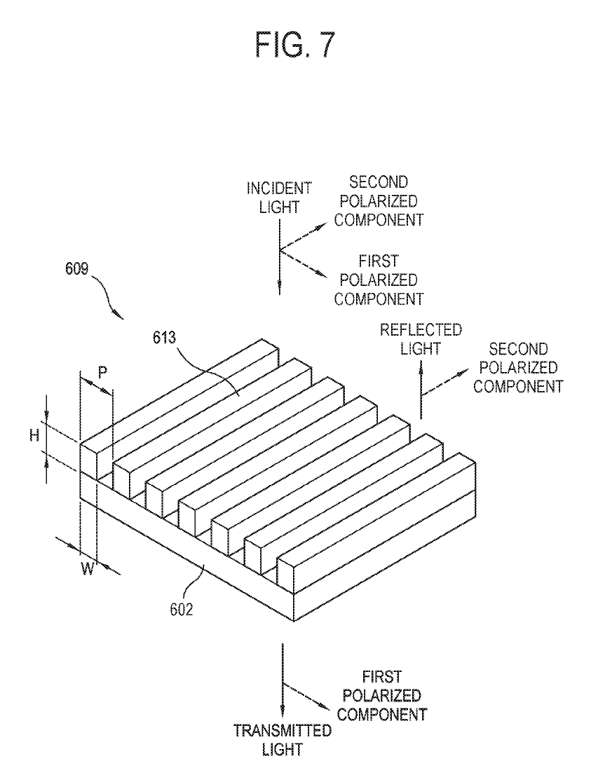

Below, referring to FIG. 7, the polarization layer 609 of the display panel 600 will be described in detail. FIG. 7 is a partial perspective view of the polarization layer 609 in the display panel 600. In FIG. 7, the polarization layer 609 stacked on the bottom of the second substrate 602 is illustrated upside down to clearly show the features of the polarization layer 609. As shown in FIG. 7, the polarization layer 609 is achieved in such a manner that linear lattices each shaped like a bar extended in a certain direction are arranged in parallel on the second substrate 602. The linear lattice 613 has a thickness H, a width W and a pitch P which are previously set. When the pitch P between the linear lattices 613 is adjusted to be ½ of a wavelength of incident light, it is possible to make only transmission light (i.e. the light of the first polarized component) and reflection light (i.e. the light of the second polarized component) without diffracted waves. A slit is formed between two adjacent linear lattices 613. While the incident light passes through the slit, the first polarized component corresponding to a first polarization direction perpendicular to the extended direction of the linear lattice 613 passes through the polarization layer 609. On the other hand, the second polarized component corresponding to a second polarization direction parallel with the extended direction of the linear lattice 613 is reflected again. That is, with this structure of the linear lattice 613, light passing through the polarization layer 609 is polarized in the first polarization direction. In other words, the extended direction of the linear lattice 613 is determined in accordance with the polarized direction of the light that can pass through the polarization layer 609. The linear lattice 613 of the polarization layer 609 includes a metallic material capable of reflecting light. Therefore, the second polarized component of the internal light, which cannot pass through the polarization layer 609, is reflected from the linear lattice 613 toward the inside of the display panel 600, is reflected again from the first electrode layer 603 or the second electrode layer 604 and travels again toward the polarization layer 609. That is, on the contrary to that the absorption layer 210 of the display panel 200 of FIG. 2 absorbs the light of the second polarized component, the polarization layer 609 does not absorb but reflects again the light of the second polarized component that cannot pass through the polarization layer 609, thereby recycling the internal light.

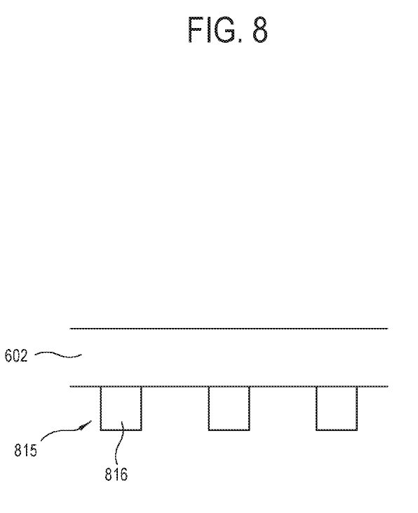

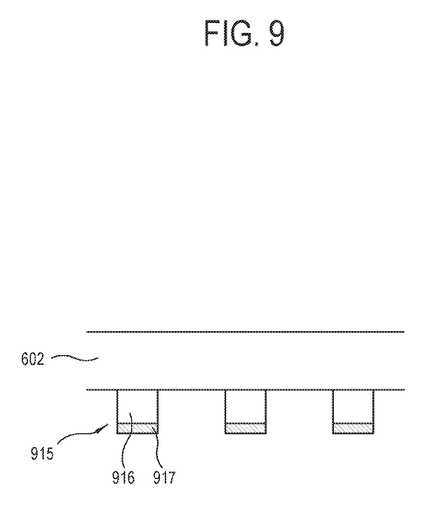

FIG. 8 and FIG. 9 are lateral cross-section views of showing examples of the linear lattice. As shown in FIG. 8, one linear lattice 815 may include a metal layer 816 stacked on the bottom of the second substrate 602 to face toward the inside of the display panel 600. The metal layer 816 includes a metal material such as Au, Al, Cu, Ag, etc. easy to reflect light, and does not transmit but reflects the light of the second polarized component toward the inside of the display panel 600. As shown in FIG. 9, one linear lattice 915 may include a metal layer 916 and an insulation layer 917 which are stacked in sequence on the bottom of the second substrate 602 to face toward the inside of the display panel 600. FIG. 9 illustrates that the insulation layer 917 is placed beneath the metal layer 916. Alternatively, the insulation layer 917 may be interposed between the second substrate 602 and the metal layer 91, or may be stacked on both the top and bottom of the metal layer 916. The insulation layer 917 may be made of various materials including SiO2, and have a predetermined strength to protect a metal layer 916, which may be damaged, from the outside. Further, the insulation layer 917 is required to have a predetermined electric conductivity or below to insulate the metal layer 916 from the second substrate 602 or the second electrode layer 604. As shown in the examples of FIG. 8 and FIG. 9, the linear lattices 815 and 915 of the examples respectively include the metal layers 816 and 916 for reflecting light, thereby not absorbing but rather reflecting the non-transmitted light of the second polarized component.

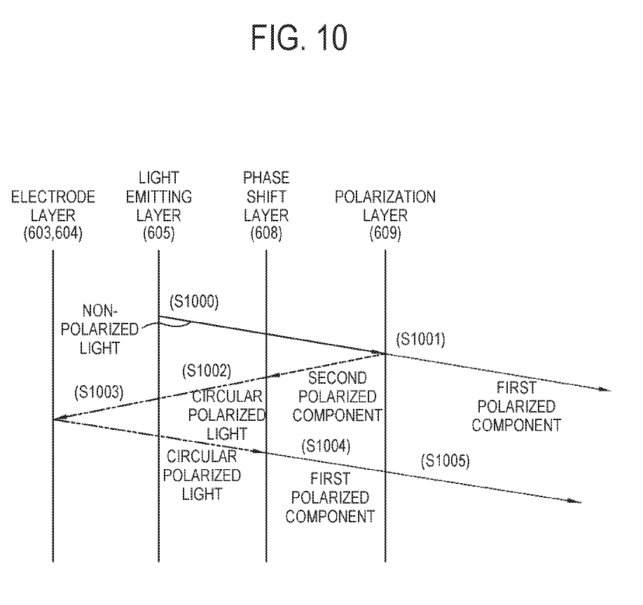

FIG. 10 illustrates an example for describing processes in which polarization properties of light emitted from the display panel of FIG. 6 are changed step by step. As shown in FIG. 10, internal light is emitted from the light emitting layer 605 S1000 as non-polarized light that is not changed in polarization properties even though it passes through the phase shift layer 608. The polarization layer 609 transmits the light of the first polarized component of the non-polarized light passed through the phase shift layer 608, but reflects the light of the second polarized component not passed through the polarization layer 609 toward the inside of the display panel 600 (S1001). The light of the second polarized component reflected toward the inside of the display panel 600 is charged into the circular polarized light while passing through the phase shift layer 608 (S1002), and reflected again by one of the first electrode layer 603 and the second electrode layer 604 (S1003). When the circular polarized light passes through the phase shift layer 608, the circular polarized light is changed into the light of the first polarized component (S1004), and thus the changed light of the first polarized component can pass through the polarization layer 609 (S1005). That is, the light of the second polarized component, which does not pass through the polarization layer 609, of the internal light emitted from the light emitting layer 605 is changed into the light of the first polarized component and then recycled, thereby enhancing the optical efficiency of the display panel 600.

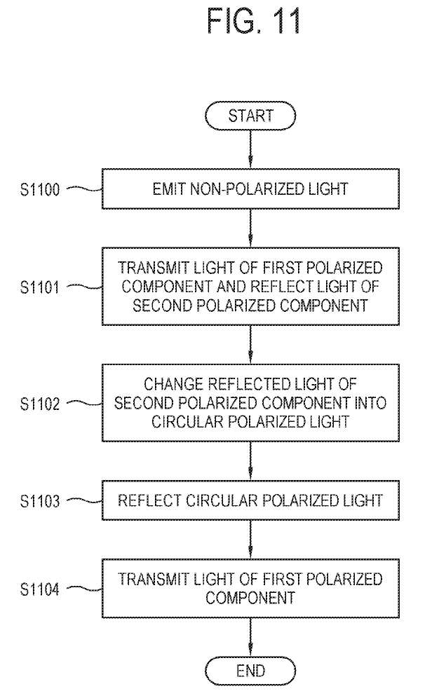

FIG. 11 is a flowchart for describing processes in which polarization properties of the internal light emitted from the light emitting layer 605 of the display panel 600 of FIG. 6 are changed step by step, in which the steps from S1100 to S1105 of FIG. 11 correspond to those S1000 to S1005 of FIG. 10, and thus repetitive detailed descriptions thereof are omitted.

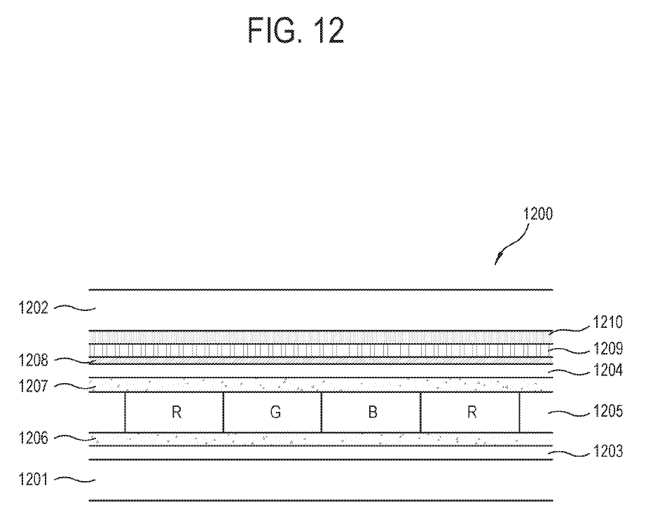

FIG. 12 is a lateral cross-section view of schematically showing a layered structure of a display panel 1200 according to one embodiment of the present invention. In this embodiment, the display panel 1200 includes a first substrate 1201, a second substrate 1202 arranged to face the first substrate 1201, a first electrode layer 1203, a second electrode layer 1204 arranged to face the first electrode layer 1203, a light emitting layer 1205 interposed between the first electrode layer 1203 and the second electrode layer 1204, an electron transport layer 1206 interposed between the first electrode layer 1203 and the light emitting layer 1205, a hole transport layer 1207 interposed between the light emitting layer 1205 and the second electrode layer 1204, a polarization layer 1209 interposed between the second substrate 1202 and the second electrode layer 1204, and a phase shift layer 1208 interposed between the polarization layer 1209 and the second electrode layer 1204, and these elements have the same functions as those included in the display panel 600 of FIG. 6. In addition, the display panel 1200 includes an absorption layer 1210 interposed between the second substrate 1202 and the polarization layer 1209. That is, the absorption layer 1210, the polarization layer 1209 and the phase shift layer 1208 are arranged in sequence between the second substrate 1202 and the second electrode layer 1204. The absorption layer 1210 may be achieved by a polarization film. That is, the absorption layer 1210 may be achieved by tri-acetate cellulose (TAC) films centering on a polarization element made of a poly vinyl alcohol (PVA) film dyed with a dichromatic material, and the polarization element is attached with protection layers for protection at both sides thereof. This structure is called a three-layered structure of TAC-PVA-TAC, which is the most basic form of the polarization film. The TAC film serving as a protection layer may be subjected to a surface coating process for scattering, hardness enhancement, anti-reflection, low reflection, and the like features in accordance with required features.

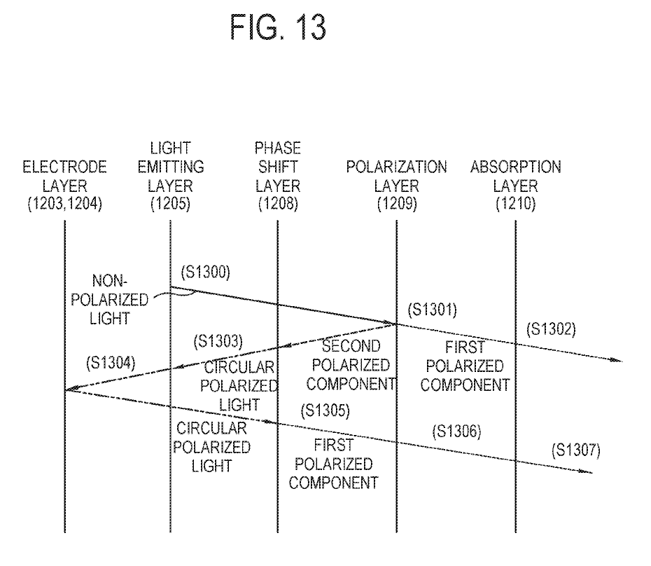

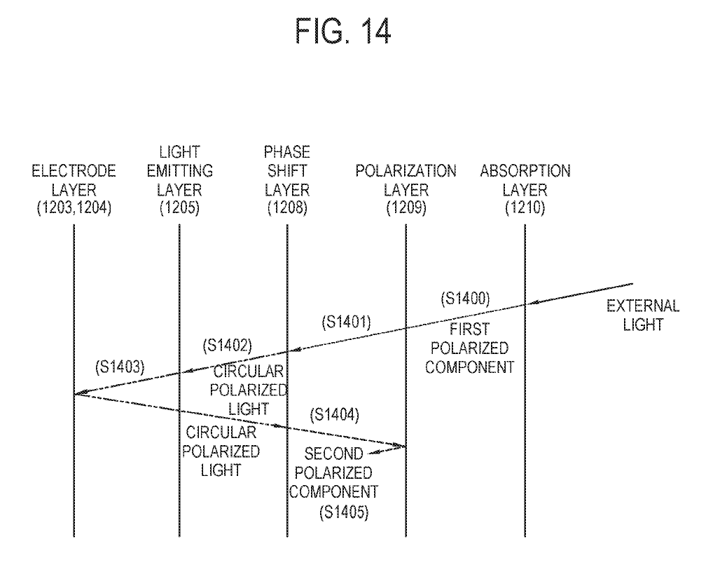

Below, referring to FIG. 13 and FIG. 14, it will be described that the polarization properties of the internal light emitted from the display panel 1200 of FIG. 12 are changed step by step. FIG. 13 illustrates an example for describing processes in which polarization properties of the internal light emitted from the light emitting layer 1205 of the display panel 1200 in this embodiment are changed step by step. The light emitting layer 1205 of the display panel 1200 emits non-polarized light (S1300). The non-polarized light has no phase shift even though it passes through the phase shift layer 1208. Regarding the non-polarized light, the polarization layer 1209 transmits the light of the first polarized component, but reflects the light of the second polarized component toward the inside of the display panel 1300 (S1301). The light of the first polarized component passed through the polarization layer 1209 is not absorbed in the absorption layer 1210 but exits from the display panel 1200 (S1302). Meanwhile, the light of the second polarized component reflected toward the inside of the display panel 1200 is changed into the circular polarized light while passing through the phase shift layer 1208 (S1303), and the circular polarized light is reflected again by the first electrode layer 1203 and the second electrode layer 1204 (S1304). When the circular polarized light passes through the phase shift layer 1208, it is changed into the light of the first polarized component (S1305), and the light of the first polarized component passes through the polarization layer 1209 and exits from the display panel 1200 without being intercepted by the absorption layer 1210 (S1307). Thus, the display panel 1200 according to this embodiment may fully use the internal light emitted from the light emitting layer 1205, thereby enhancing the optical efficiency of the internal light.

FIG. 14 illustrates an example for describing processes in which polarization properties of external light incident upon the display panel 1200 are changed step by step. The external light is the non-polarized light. When the external light is incident up on the absorption layer 1210 of the display panel 1200, the absorption layer 1210 absorbs the light of the second polarized component, but transmits the light of the first polarized component toward the inside of the display panel 1200 (S1400). Since the light of the first polarized component can transmit the polarization layer 1209, it is changed into the circular polarized light while passing through the phase shift layer 1208 (S1402). The circular polarized light is reflected from the first electrode layer 1203 and the second electrode layer 1204 (S1403), and changed into the light of the second polarized component by the phase shift layer 1208 (S1404). The light of the second polarized component is reflected again from the polarization layer 1209 toward the inside of the display panel 1200 (S1405). That is, the display panel 1200 according to an embodiment can prevent contrast from being decreased by the external light since it can prevent the reflection of the external light.

Comparison in the optical efficiency and the reflectivity of the external light between the display panel 200 including only the absorption layer 210 as shown in FIG. 2 and the display panel 1200 including both the absorption layer 1210 and the polarization layer 1209 are as follows. Let the transmittance of the absorption layer 210, 1210 and the polarization layer 1209 to the light of the first polarized component be TTM, the reflectivity of the polarization layer 1209 to the light of the second polarized component be RWGP, the reflectivity of the absorption layer 210, 1210 to the light of the second polarized component be RAR, the transmittance of the light emitting layer 205, 1205 be TOLED, the reflectivity of the first electrode layer 203, 1203 or the second electrode layer 204, 1204 be RMETAL, and the transmittance of the phase shift layer 208, 1208 be TRTD. With this, the optical efficiency T and the reflectivity R of the external light are calculated as follows.

T=T_{RTD}·(½·T_{TM}+½·R_{WGP}·C·T_{TM})=½·T_{TM}·T_{RTD}·(1+C·R_{WGP})

R=½·R_{AR}+½·T_{TM}·C·R_{WGP}·C·T_{TM}=½·(R_{AR}+C²·R_{WGP}·T_{TM}²)

In this case, C indicates a reciprocation cycle between the phase shift layer 208, 1208, the light emitting layer 205, 1205 and the first electrode layer 203, 1203 or the second electrode layer 204, 1204, C is calculated as follows.

C=T_{RTD}·T_{LED}·R_{METAL}·T_{OLED}·T_{RTD}=R_{METAL}·T_{OLED}²·T_{RTD}²

For example, let the transmittance TTM of the absorption layer 210, 1210 and the polarization layer 1209 to the light of the first polarized component the transmittance be 90%, the reflectivity RWGP of the polarization layer 1209 to the light of the second polarized component be 90%, the reflectivity RAR of the absorption layer 210, 1210 to the light of the second polarized component be 5%, the transmittance TOLED of the light emitting layer 205, 1205 be 70%, the reflectivity RMETAL of the first electrode layer 203, 1203 or the second electrode layer 204, 1204 be 90%, and the transmittance TRTD of the phase shift layer 208, 1208 be 90%. In this case, the optical efficiency T of the display panel 1200 and the reflectivity R of the external light are calculated as follows.

T=T_{RTD}·(½·T_{TM}+½·R_{WGP}·C·T_{TM})=½·T_{TM}·T_{RTD}·(1+C·R_{WGP})=53.5%

R=½·R_{AR}+½·T_{TM}·C·R_{WGP}·C·T_{TM}=½·(R_{AR}+C²·R_{WGP}·T_{TM}²)=7.2%

Since the display panel 200 excluding the polarization layer 1209 for reflecting the light of the second polarized component has a reflectivity RWGP of 0 to the light of the second polarized component, the display panel 200 has an optical efficiency T=40.5% and a reflectivity R of 2.5% to the external light. In other words, the display panel 1200 including not only the absorption layer 1210 but also the polarization layer 1209 is more improved in the optical efficiency T by 13% than the display panel 200 including only the absorption layer 210.

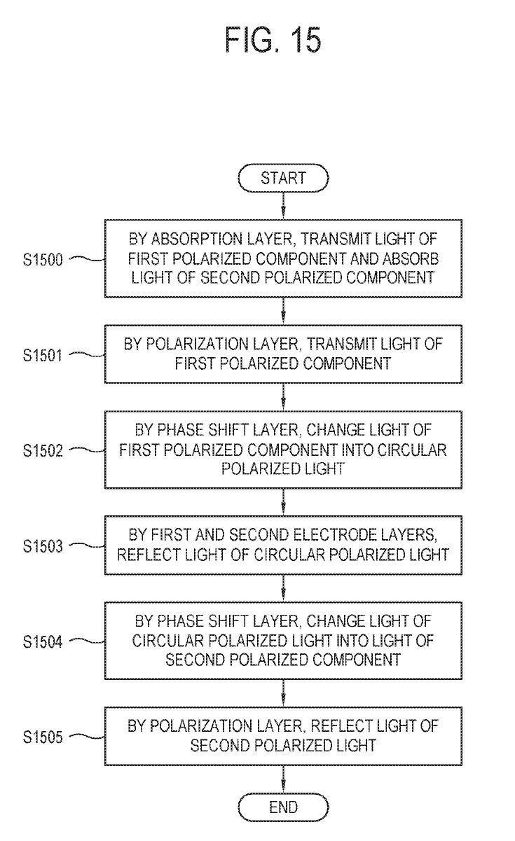

FIG. 15 is a flowchart for describing processes in which polarization properties of external light incident upon the display panel 1200 of FIG. 12 are changed step by step, in which the steps from S1500 to S1505 of FIG. 15 correspond to those S1400 to S1405 of FIG. 14 and thus repetitive detailed descriptions thereof are omitted.

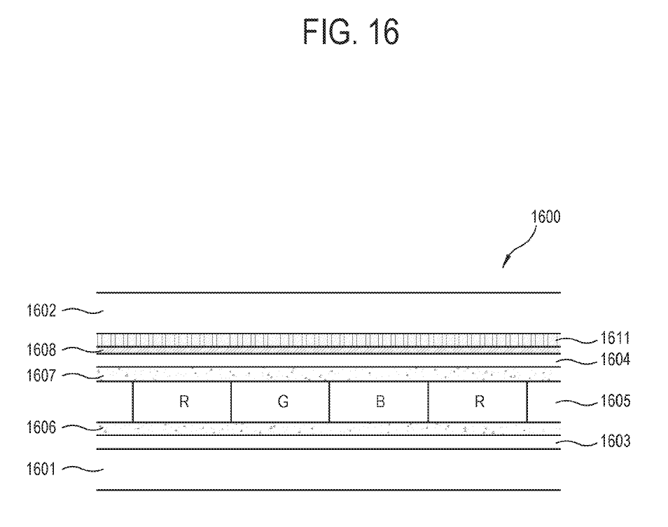

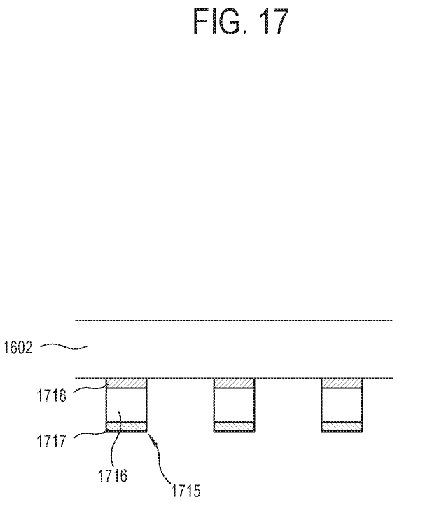

Below, referring to FIG. 16 and FIG. 17, an absorption polarization layer 1611 configured with a linear lattice 1715 and a display panel 1600 including the absorption polarization layer 1611 will be described. FIG. 16 is a lateral cross-section view of schematically showing a layered structure of the display panel 1600 including the absorption polarization layer 1611 according to one embodiment of the present invention, and FIG. 17 is a lateral cross-section view of a linear lattice 1715 of the absorption polarization layer 1611 in the display panel 1600 of FIG. 16.

The linear lattice 1715 of the absorption polarization layer 1611 includes a metal layer 1716 stacked on the bottom of a second substrate 1602, an absorption layer 1718 interposed between the second substrate 1602 and the metal layer 1716, and an insulation layer 1717 stacked on the bottom of the metal layer 1716 to face the absorption layer 1718. Unlike the absorption layer 210, 1210 of the display panel 200, 1200, the absorption layer 1718 of the display panel 1600 includes various materials such as AlAs, GaAs, InGaAs, GaP, GaN, InN, CdTe, Ni—P, carbon nano tube (CNT), Ag2S, Cr2O3, FeSi2, black paint, etc. In particular, the absorption layer 1718 of the display panel 1600 has the same function as the absorption layer 1210 of the display panel 1200 shown in FIG. 12. However, the absorption layer 1210 of the display panel 1200 shown in FIG. 12 is provided separately from the polarization layer 1209 and stacked on the polarization layer 1209, whereas the absorption layer 1718 of the display panel 1600 may be alternatively applied to the linear lattice 1715 by glancing angle deposition (GLAD) to thereby form one absorption polarization layer 1611. The absorption layer 1210 and the polarization layer 1209 of the display panel 1200 of FIG. 12 has a thickness of about 100 μm, whereas the absorption polarization layer 1611 of the display panel 1600 may have a thickness of 1 μm to thereby innovatively decrease the thickness of the display panel 1200. Therefore, the display panel 1600 including the absorption polarization layer 1611 is thinner than the display panel 1200 of FIG. 12 including the absorption layer 1210 and the polarization layer 1209, thereby enhancing the optical efficiency of the internal light and preventing the contrast from being decreased by the external light. That is, the absorption polarization layer 1611 including the linear lattice 1715 transmits the first polarized component of the internal light emitted from the light emitting layer 1605 to the outside of the display panel 1600, bur reflects the light of the second polarized component toward the inside of the display panel 1600 to thereby recycle the reflected light of the second polarized component. Further, the absorption polarization layer 1611 transmits the first polarized component of the external light, and absorbs the light of the second polarized component, thereby preventing the contrast from being decreased by the reflection of the external light.

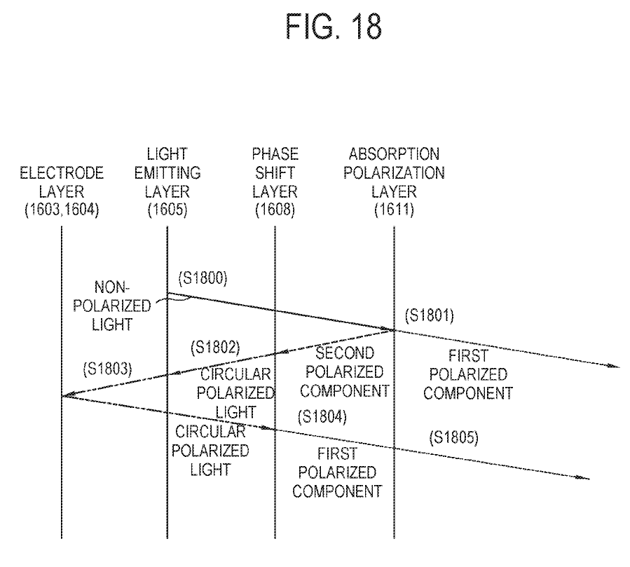

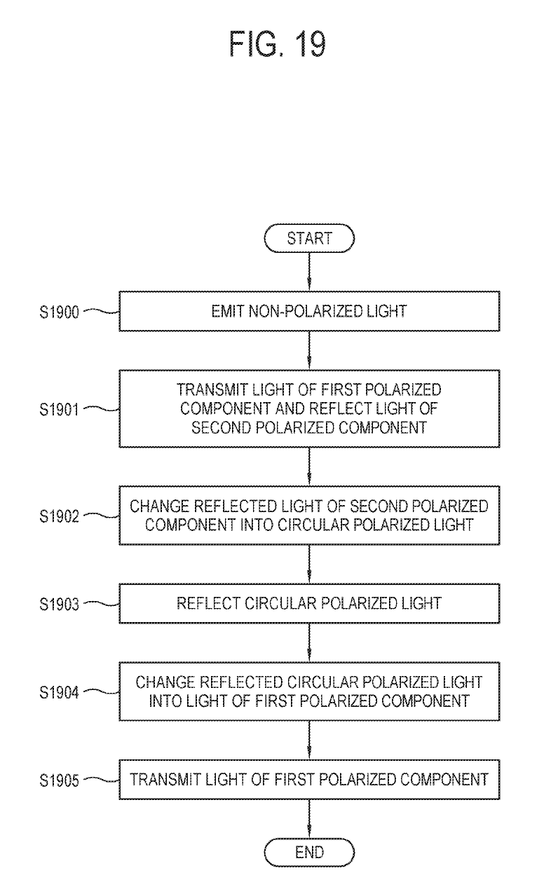

Below, referring to FIG. 18 and FIG. 19, it will be described that polarization properties of light emitted from the light emitting layer 1605 in the display panel 1600 including the absorption polarization layer 1611 are changed step by step. The light emitting layer 1605 of the display panel 1600 emits non-polarized light (S1800). The absorption polarization layer 1611 transmits the light of the first polarized component to the outside of the display panel 1600, but reflects the light of the second polarized component to the inside of the display panel 1600 (S1801). The light of the second polarized component reflected inward is changed into the circular polarized light by the phase shift layer 1608 (S1802), and reflected toward at least one of the first electrode layer 1603 and the second electrode layer 1604 (S1803). The reflected circular polarized light is changed into the light of the first polarized component by the phase shift layer 1608 (S1804), and the light of the first polarized component exits to the outside of the display panel 1600 (S1805). That is, the display panel 1600 recycles the light of the second polarized component and enhances the optical efficiency of the display panel 1600.

Meanwhile, the steps S1900 to S1905 of FIG. 19 correspond to the steps S1800 to S1805 of FIG. 18, and thus repetitive detailed descriptions are omitted.

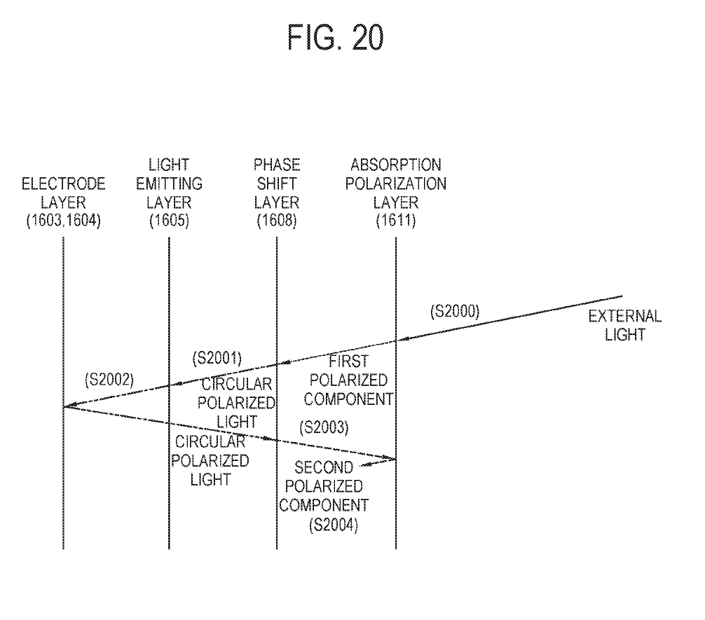

FIG. 20 illustrates an example for describing processes in which polarization properties of external light incident upon the display panel 1600 including the absorption polarization layer 1611. When the non-polarized external light is incident upon the display panel 1600, the absorption polarization layer 1611 transmits the light of the first polarized component, but absorbs the light of the second polarized component (S2000). The transmitted light of the first polarized component is changed into the circular polarized light by the phase shift layer 1608 (S2001), and the circular polarized light is reflected from at least one of the first electrode layer 1603 and the second electrode layer 1604 (S2002). The reflected circular polarized light is changed into the light of the second polarized component by the phase shift layer 1608 (S2003), and the light of the second polarized component is reflected toward the inside of the display panel 1600 by the absorption polarization layer 1611. Therefore, the display panel 1600 can prevent the contrast from being decreased by the reflection of the external light. Like this, the display panel 1600 including the absorption polarization layer 1611 configured with the linear lattice 1715 is thinner than the display panel 1200 of FIG. 12, and is capable of enhancing the optical efficiency of the internal light and preventing the contrast from being decreased by the external light.

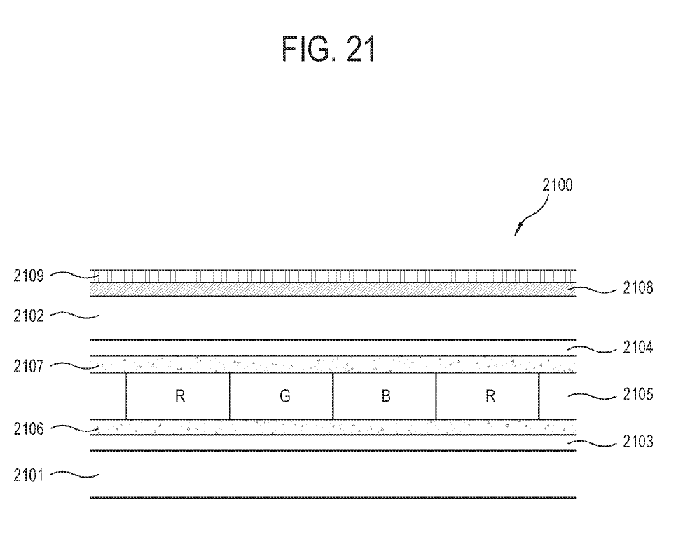

FIG. 21 is a lateral cross-section view of schematically showing a layered structure of a display panel 2100 according to one embodiment of the present invention. The display panel 2100 includes a phase shift panel 2108 and a polarization panel 2109 which are sequentially stacked on the top of a second substrate 2102. Changes in the polarization properties of the internal light emitted from the light emitting layer 2105 of the display panel 2100 are the same as described above. Therefore, it is possible to improve the optical efficiency of the internal light through the display panel 2100.

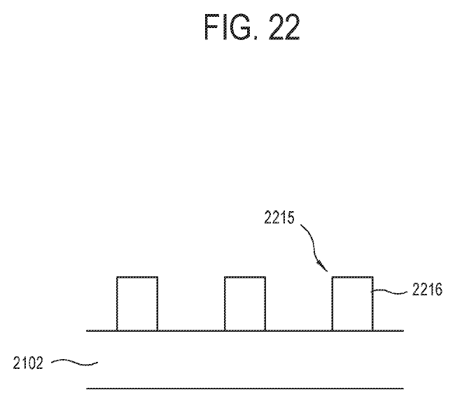

However, FIG. 22 shows a linear lattice 2215 of the polarization panel 2109 in the display panel 2100. Since the linear lattice 2215 includes a metal lattice 2216, the external light incident upon the display panel 2100 is reflected, thereby decreasing the contrast of the display panel 2100.

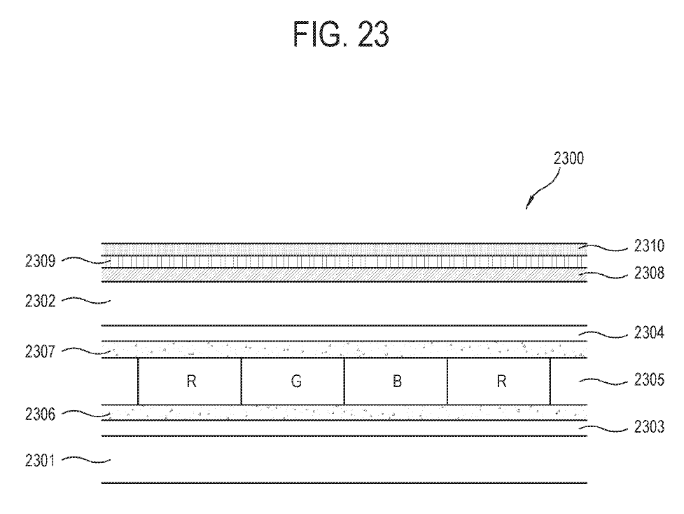

To prevent this, as shown in the display panel 2300 of FIG. 23, an absorption layer 2310 is stacked on the top of the polarization layer 2309, transmits only the first polarized component of the external light incident upon the display panel 2300 and absorbs light of the second polarized component, thereby preventing the contrast from being decreased by the display panel 2300.

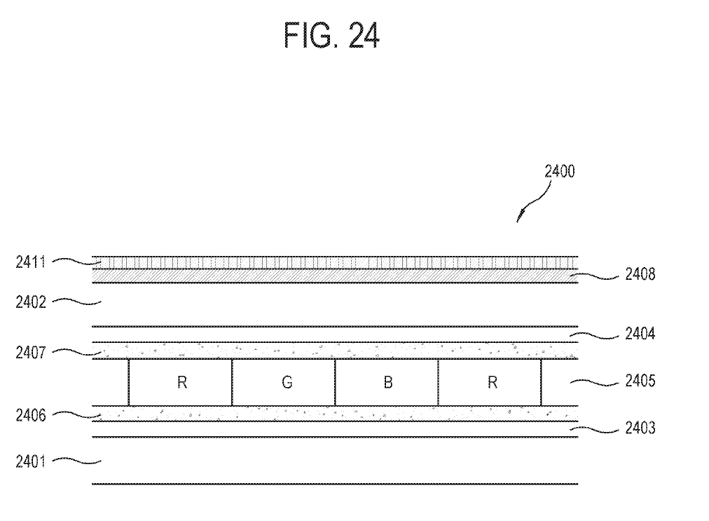

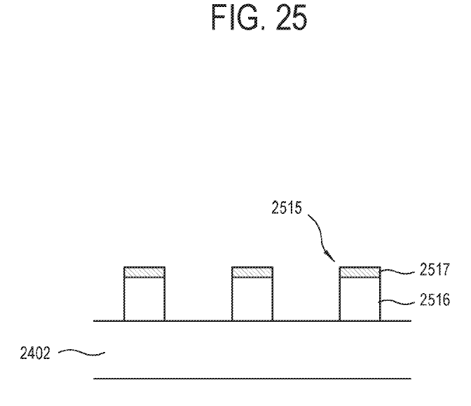

Meanwhile, unlike the display panel 2300 of FIG. 23 including the absorption layer 2310 stacked on the top of the polarization layer 2309, a display panel 2400 of FIG. 24 includes an absorption polarization layer 2411 configured with a linear lattice 2515, in which an absorption layer 2517 is applied on to a metal layer 2516 as shown in FIG. 25, and is thus thinner than the display panel 2300 of FIG. 23, thereby enhancing the optical efficiency of the internal light and preventing the contrast from being decreased by the external light.

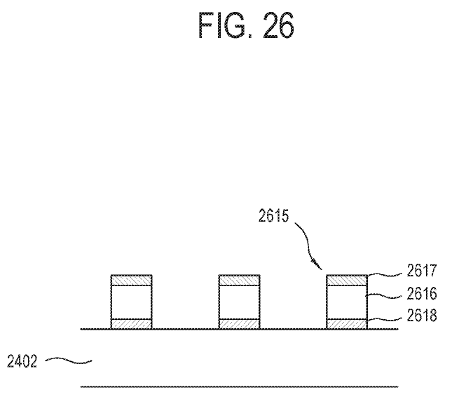

Further, the absorption polarization layer 2411 of the display panel 2400 shown in FIG. 24 may include a linear lattice 2615, in which an absorption layer 2617 is applied on to a metal layer 2616 and an insulation layer 2618 is applied between a second substrate 2402 and the metal layer 2616, as shown in FIG. 26. In this case, the absorption layer 2615 may have a predetermined strength to protect the metal layer 2616 from the outside, and the insulation layer 2618 may have a predetermined electric conductivity or below to insulate the metal layer 2616.

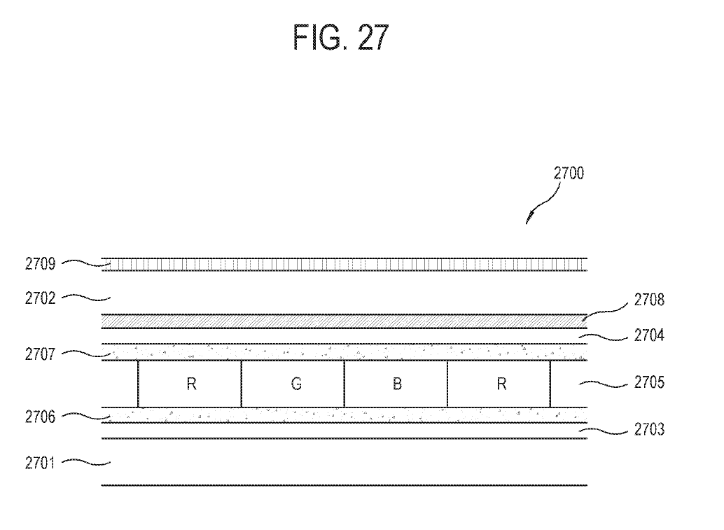

FIG. 27 is a lateral cross-section view of schematically showing a layered structure of a display panel 2700 according to one embodiment of the present invention. The display panel 2700 may be achieved by interposing a phase shift layer 2708 between a second substrate 2702 and a second electrode layer 2704, and stacking a polarization layer 2709 on the top of the second substrate 2702. The display panel 2700 can recycle light, which does not transmit but is reflected from the polarization layer 2709, of the internal light emitted from a light emitting layer 2705, thereby enhancing the optical efficiency of the display panel 2700.

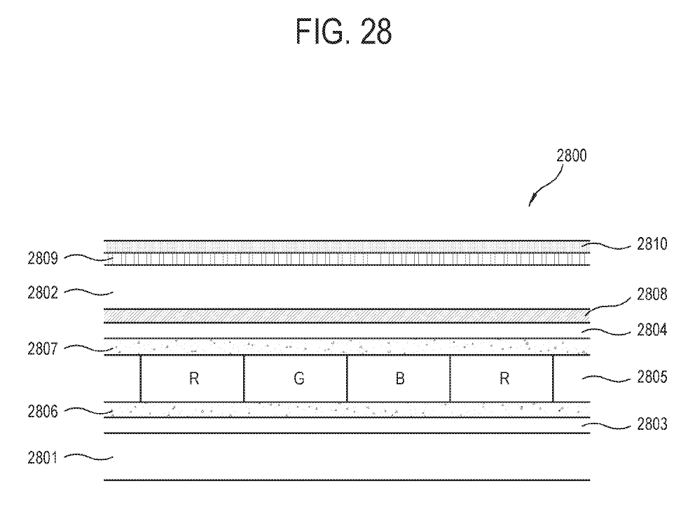

FIG. 28 is a lateral cross-section view of schematically showing a layered structure of a display panel 2800 according to one embodiment of the present invention. The display panel 2800 may be achieved by stacking an absorption layer 2810 on the top of the polarization layer 2709 of the display panel 2700 shown in FIG. 27. The display panel 2800 recycles light, which does not transmit but is reflected from the polarization layer 2809, of internal light emitted from a light emitting layer 2805, thereby enhancing the optical efficiency of the display panel 2800 but also preventing the reflection of the external light.

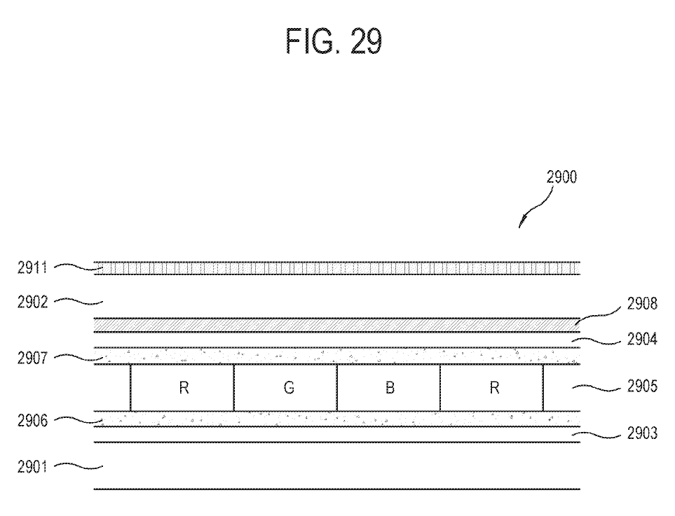

FIG. 29 is a lateral cross-section view of schematically showing a layered structure of a display panel 2900 according to one embodiment of the present invention, in which the display panel 2900 includes a single absorption polarization layer 2911 unlike the display panel 2800 of FIG. 28 where the absorption layer 2810 and the polarization layer 2809 are separately provided. Thus, the display panel 2900 is thin but enhances the optical efficiency of the internal light and prevents the reflection of the external light.

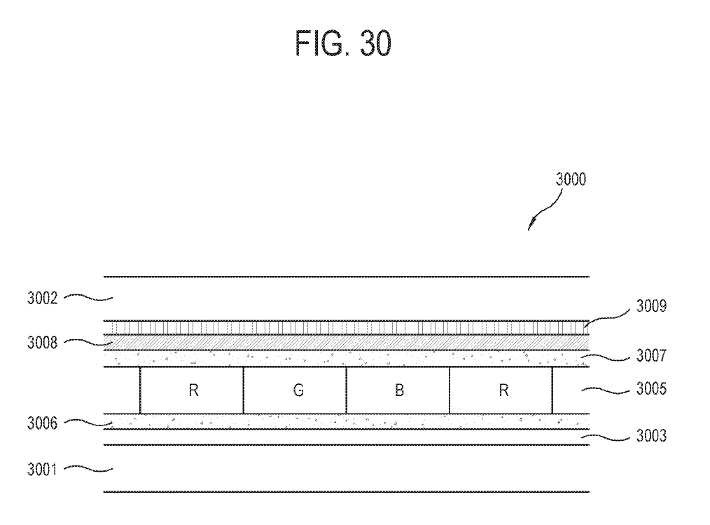

FIG. 30 is a lateral cross-section view of schematically showing a layered structure of a display panel 3000 according to one embodiment of the present invention. Since the linear lattice of the polarization layer 3009 of the display panel 3000 may include highly conductive metal materials, it may serve as an anode for generating holes when a positive voltage (+) is applied to the linear lattice of the polarization layer 3009. In other words, when negative (−) and positive (+) voltages are applied to a first electrode layer 3003 and the polarization layer 3009 of the display panel 3000, electrons are generated in the first electrode layer 3003 used as a cathode, and holes are generated in the polarization layer 3009 used as the anode. An electron transport layer 3006 transports the electrons generated in the first electrode layer 3003 to the light emitting layer 3005, and a hole transport layer 3007 transports the holes generated in the polarization layer 3009 to the light emitting layer 3005. The light emitting layer 3005 emits light in proportion to an electric current flowing from the anode, i.e. the polarization layer 3009 toward the cathode, i.e. the first electrode layer 3003. That is, the display panel 3000 includes the polarization layer 3009 to replace the second electrode layer, thereby making it possible to reduce the thickness of the display panel 3000 but also simplifying a manufacturing process. Further, the polarization layer 3009 is capable of recycling light of the second polarized component, which does not transmit but is reflected from the polarization layer 3009, of the internal light emitted from the light emitting layer 3005. Therefore, the polarization layer 3009 can enhance the optical efficiency of the display panel 3000.

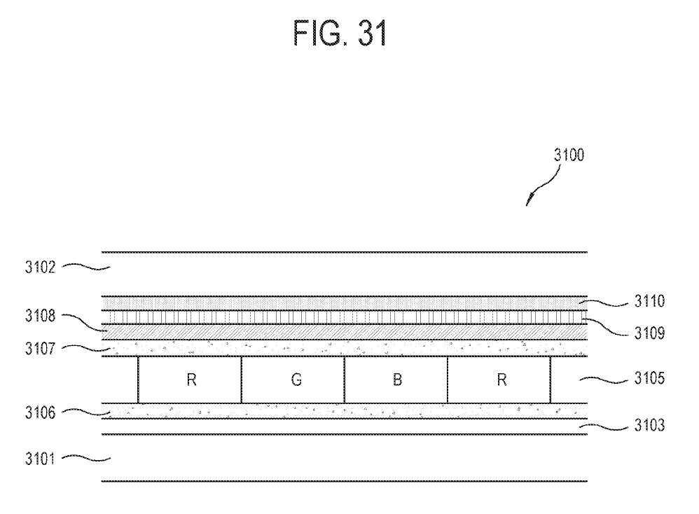

FIG. 31 is a lateral cross-section view of schematically showing a layered structure of a display panel 3100 according to one embodiment of the present invention. The display panel 3100 includes an absorption layer 3110 stacked on a top of a polarization layer 3109 in order to replace the second electrode layer. The absorption layer 3110 prevents the contrast from being decreased by the reflection of the light incident upon the display panel 3100.

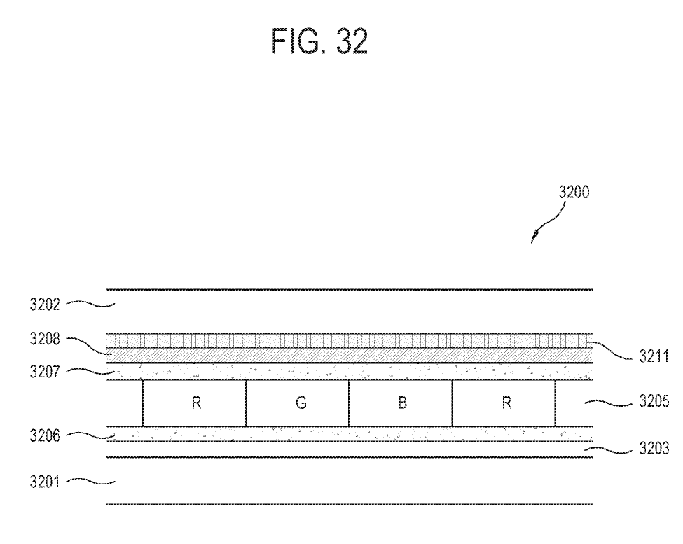

FIG. 32 is a lateral cross-section view of schematically showing a layered structure of a display panel 3200 according to one embodiment of the present invention. The display panel 3200 includes an absorption polarization layer 3211 formed by applying an absorption layer 3110 onto a polarization layer 3109 by the GLAD in order to replace the second electrode layer of the display panel 3100. Thus, the display panel 3200 may be thinner than the display panel 3100 of FIG. 31.

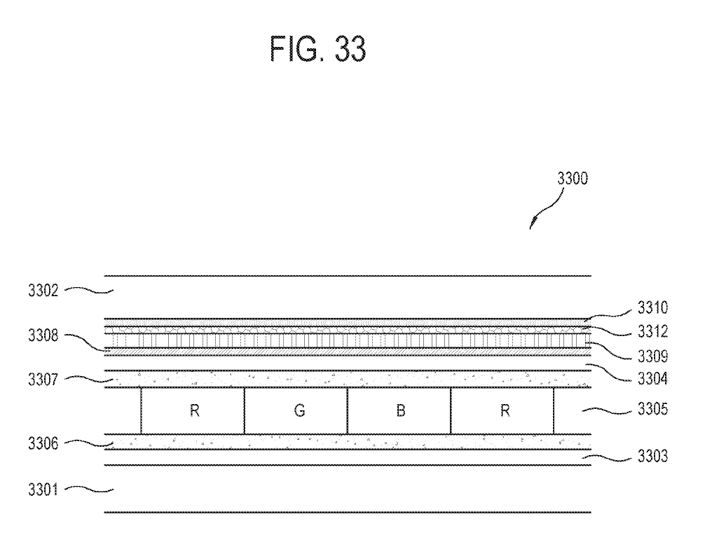

FIG. 33 is a lateral cross-section view of schematically showing a layered structure of a display panel 3300 according to one embodiment of the present invention. The display panel 3300 includes a first substrate 3301, a second substrate 3302 arranged to face the first substrate 3301, a first electrode layer 3303, a second electrode layer 3304 arranged to face the first electrode layer 3303, a light emitting layer 3305 interposed between the first electrode layer 3303 and the second electrode layer 3304, an electron transport layer 3306 interposed between the first electrode layer 3303 and the light emitting layer 3305, a hole transport layer 3307 interposed between the light emitting layer 3305 and the second electrode layer 3304, a polarization layer 3309 interposed between the second substrate 3302 and the second electrode layer 3304, a phase shift layer 3308 interposed between the polarization layer 3309 and the second electrode layer 3304, and an absorption layer 3310 between the second substrate 3302 and the polarization layer 3309. These elements have the same functions as those of the display panel 1200 shown in FIG. 12, respectively. In addition, the display panel 3300 may include a buffer layer 3312 interposed between the absorption layer 3310 and the polarization layer 3309. FIG. 33 shows that the buffer layer 3312 is interposed between the absorption layer 3310 and the polarization layer 3309, but it is not limited thereto. Alternatively, the buffer layer 3312 may be interposed between the second substrate 3302 and the absorption layer 3310. The buffer layer 3312 may be provided in the form of a film, and the absorption layer 3310 is varied in the absorptivity of the light of the second polarized component and the transmittance of the light of the first polarized component depending on the thickness H of the buffer layer 3312. Therefore, it is possible to optimize the absorptivity of the light of the second polarized component and the transmittance of the light of the first polarized component in the display panel 3300 by adjusting the thickness of the buffer layer 3312.

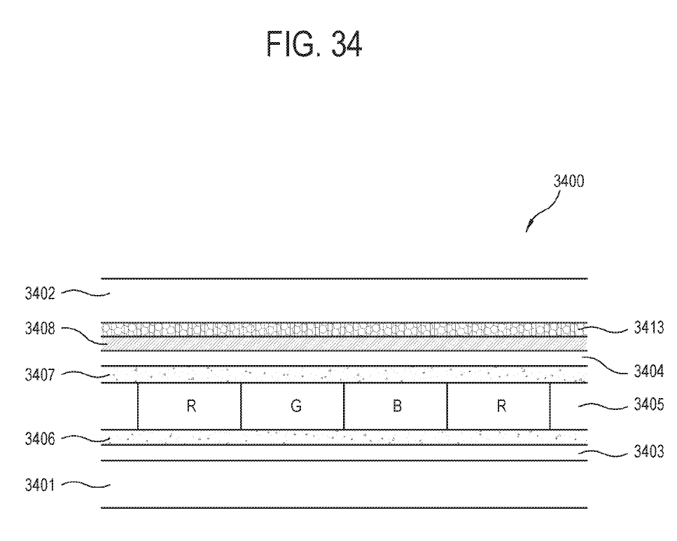

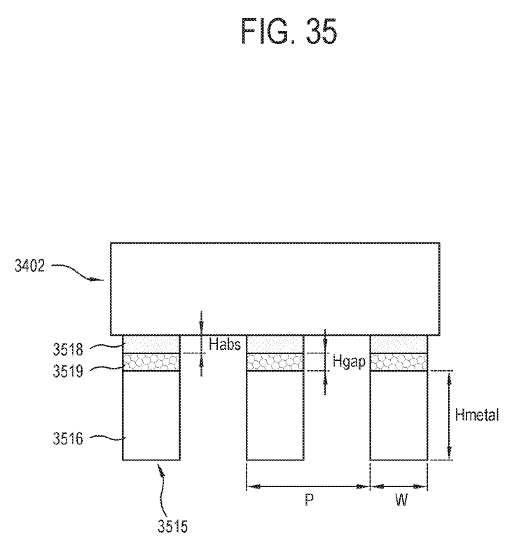

Unlike the display panel 3300 of FIG. 33 in which the absorption layer 3310, the buffer layer 3312 and the polarization layer 3309 are stacked in sequence, the display panel 3400 of FIG. 34 includes a buffer polarization layer 3413 configured with a linear lattice 3515 in which a buffer layer 3519 and an absorption layer 3518 are sequentially applied to a top of a meta layer 3516 as shown in FIG. 35. Below, referring to FIGS. 34 and 35, the display panel 3400 including the buffer polarization layer 3413 will be described. The buffer polarization layer 3413 includes the linear lattice 3515 that can be formed by applying the buffer layer 3519 made of SiO2, Si3N4, WO3, TiO2, etc. on to the metal layer 3516, and applying the absorption layer 3518 on to the buffer layer 3519 by the GLAD. Alternatively, the linear lattice 3515 may be formed by sequentially depositing the absorption layer 3518, the buffer layer 3519 and the metal layer 3516 on the second substrate 3402, and patterning the linear lattice 3515 by nano-imprint lithography (NIL) or the like process. The linear lattices 3515 having a preset thickness H and width W are arranged in parallel with each other leaving a pitch P. Further, the absorption layer 3518 having a thickness Habs, the buffer layer 3519 having a thickness Hgap and the metal layer 3516 having Hmetal are formed to form the linear lattice 3515.

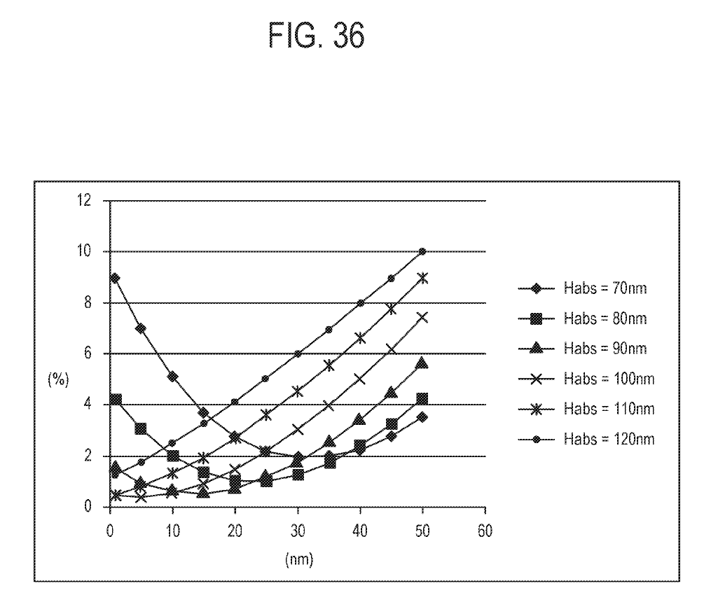

FIG. 36 is a graph of showing simulation results of reflectivity variation (%) with regard to the light of the second polarized component depending on change in thickness of the absorption layer 3518 and the buffer layer 3519, on the assumption that the absorption layer 3518 has a refractive index (n) of nabs=2 and an extinction coefficient (k) of kabs=0.75, the buffer layer 3519 has ngap=1.5 and kgap=0, and the metal layer 3516 has nmetal=0.771, kmetal=6.09 in the buffer polarization layer 3413 of FIG. 34, in which the X-axis indicates the thickness Hgap of the buffer layer 3519 and the Y-axis indicates the reflectivity (%) of the light of the second polarized component absorbed in the buffer polarization layer 3413. The refractive index (n) and the extinction coefficient (k) are not invariable, but may be varied depending on embodiments.

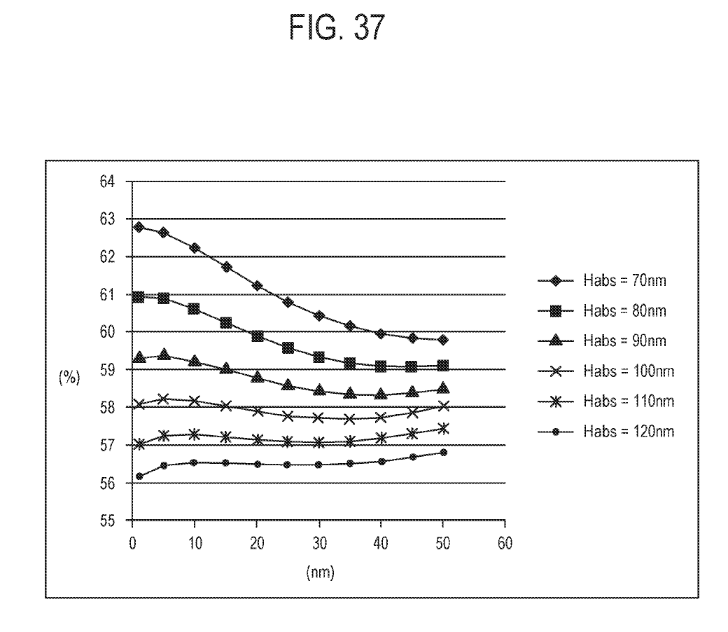

FIG. 37 is a graph of showing simulation results of transmittance variation (%) with regard to the light of the first polarized component in accordance with change in thickness of the absorption layer 3518 and the buffer layer 3519 in the buffer polarization layer 3413 of FIG. 34, in which the X-axis indicates the thickness Hgap of the buffer layer 3519 and the Y-axis indicates the transmittance (%) of the light of the first polarized component transmitting the buffer polarization layer 3413. The graph of FIG. 37 shows the transmittance of the light of the first polarized component when the thickness Habs of the absorption layer 3518 is varied from 70 nm to 120 nm in units of 10 nm, in which the transmittance of the light of the first polarized component decreases as the thickness Habs of the absorption layer 3518 increases regardless of the presence of the buffer layer 3519. Therefore, the buffer polarization layer 3413 can maximize the transmittance of the light of the first polarized component, and limits the reflectivity of the light of the second polarized component to 2% or less, i.e. the absorptivity of the second polarized component to 98% or above, when the thickness Habs of the absorption layer 3518 and the thickness Hgap of the buffer layer are respectively Habs=70 nm and Hgap=30 nm or Habs=80 nm and Hgap=10 nm. In this case, the transmittance of the light of the first polarized component approximates 60.5%. That is, when the absorption layer 3518 has a thickness Habs of 70 nm to 80 nm and the buffer layer has a thickness Hgap of 30 nm to 10 nm, it is possible to optimize the transmittance of the light of the first polarized component and the absorptivity of the second polarized component. Thus, the thickness range of the buffer layer 3519 is adjusted so that the display panel 3400 including the buffer polarization layer 3413 can increase the absorptivity of the light of the second polarized component and the transmittance of the light of the first polarized component to a predetermined lower limit value or higher. If the linear lattice 3515 of the buffer polarization layer 3413 does not include the buffer layer 3519, the thickness Habs of the absorption layer 3518 having a reflectivity of 2% or below is equal to or higher than 90 nm when a value of the X-axis is 0 in the graph of FIG. 36, and therefore the transmittance of the first polarized component corresponding to Habs=90 nm or thicker is lower than or equal to 59.5% when a value of the x-axis is 0 in FIG. 37.

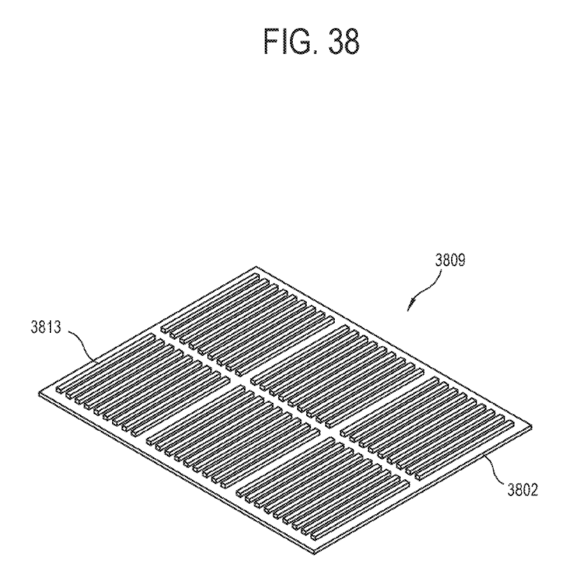

FIG. 38 is a perspective view of a large-sized polarization layer 3809 according to one embodiment of the present invention. As shown in FIG. 38, the polarization layer 3809 is formed by a process of depositing a metal layer on a second substrate 3802, and a process of patterning a linear lattice 3813 by a nano-imprint lithography (NIL) or the like process. As described above, incident light is reflected when its polarized direction is parallel with the lattice, but transmitted when its polarized direction is perpendicular to the lattice. However, there is a limit to the maximum manufacture size of one of unit lattice patterns 3813, and thus the foregoing processes have to be performed a plurality of times when a large display panel is manufactured. That is, to manufacture a large-sized polarization layer 3809 for a large display panel, a unit lattice pattern 3813 is first formed in a partial area of the second substrate 3802, and then the processes of forming the unit lattice patterns for the other areas are performed again many times, thereby forming the large-sized polarization layer 3809. The large-sized polarization layer 3809 may be formed by stacking the absorption layer and the buffer layer in a film form on the lattice pattern 3813, and may be also achieved by a buffer polarization layer where the absorption layer and the buffer layer are sequentially applied to the lattice pattern 3813.

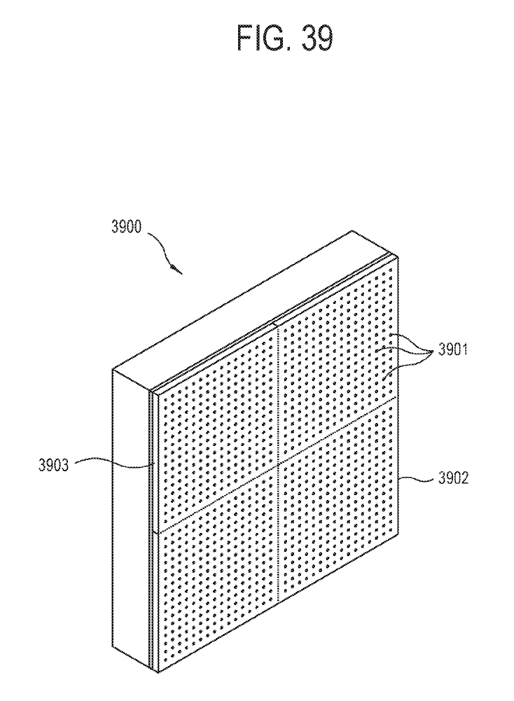

FIG. 39 is a perspective view of showing an example of a display panel 3900 according to one embodiment of the present invention. The display panel 3900 may be used as an LED signage, and may include a plurality of LED panels 3903 where M×N LED modules 3901 are formed on an electrode layer 3902. The display panel 3900 may display or advertise desired content by applying voltage to the electrode layer 3902 so that the LED modules 3901 can display a figure, a letter and a numeral. The LED module 3901 may refers to a pixel corresponding to the minimum unit of a screen, and one pixel may include a red LED, a green LED and a blue LED.

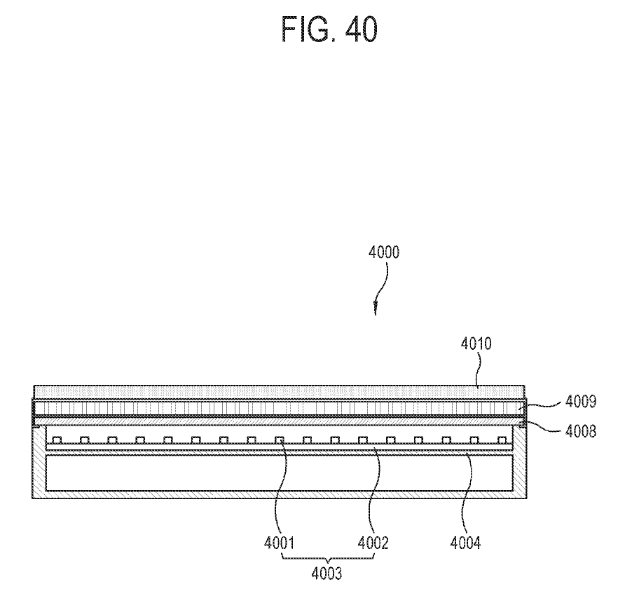

FIG. 40 is a lateral cross-section view of schematically showing a layered structure of a display panel 4000 according to one embodiment of the present invention. The display panel 4000 is formed by sequentially stacking a phase shift layer 4008, a polarization layer 4009 and an absorption layer 4010 in a light exiting direction of the display panel 3900 of FIG. 39. Below, it will be described that polarization properties of internal light of the display panel 4000 and external light incident upon the display panel 4000 are changed step by step. Since the internal light emitted by the LED panel 4003 is the non-polarized light, there are no changes in the polarization properties even it passes through the phase shift layer 4008. The polarization layer 4009 transmits the light of the first polarized component of the non-polarized light passed through the phase shift layer 4008, but reflects the light of the second polarized component toward the inside of the display panel 4000. The reflected light of the second polarized component is changed into the circular polarized light while passing through the phase shift layer 4008, and reflected again by the LED panel 4003. The reflected circular polarized light is changed into the light of the first polarized component by the phase shift layer 4008, and the polarization layer 4009 transmits the light of the first polarized component. Therefore, the optical efficiency of the display panel 4000 is increased. Further, the first polarized component of the external light passed through the absorption layer 4010 and the polarization layer 4009 is changed into the circular polarized light by the phase shift layer 4008, reflected by the LED panel 4003, and changed into the light of the second polarized component by the phase shift layer 4008. Since the light of the second polarized component is reflected again toward the inside of the display panel 4000 by the polarization layer 4009, the display panel 4000 can prevent the contrast from being decreased by the reflection of the external light.

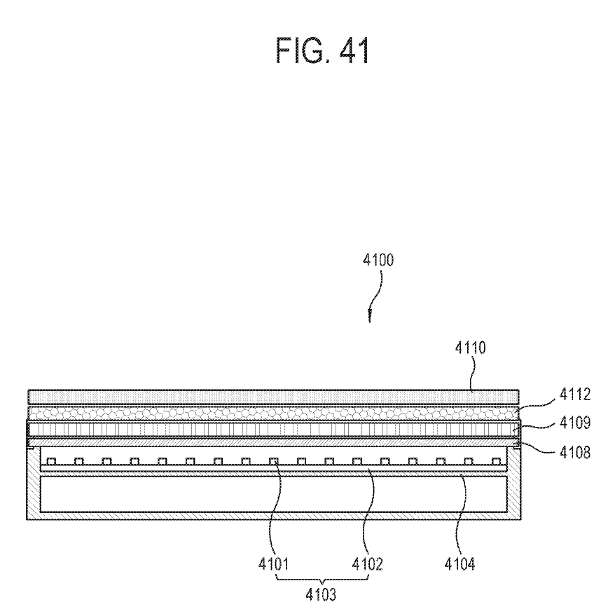

FIG. 41 is a lateral cross-section view of schematically showing a layered structure of a display panel 4100 according to one embodiment of the present invention. The display panel 4100 includes a buffer layer 4112 interposed between an absorption layer 4110 and a polarization layer 4109. However, the buffer layer 4112 may be stacked on the absorption layer 4110. As described above. The buffer layer 4112 allows the absorption layer 4110 to increase the transmittance of the light of the first polarized component and increase the absorptivity of the light of the second polarized component.

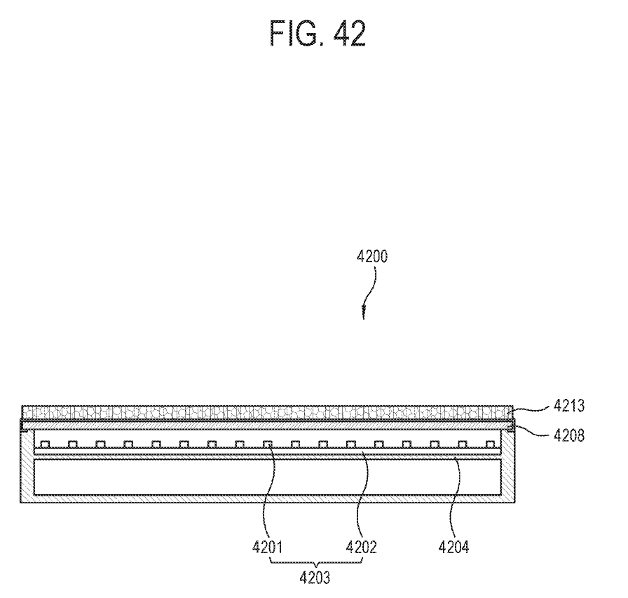

FIG. 42 is a lateral cross-section view of schematically showing a layered structure of a display panel 4200 according to one embodiment of the present invention. The display panel 4200 may include a buffer polarization layer 4213 formed by applying the absorption layer 4110 and the buffer layer 4112 to the linear lattice of the polarization layer 4109 in the display panel 4100 of FIG. 41, in which there are no limits to applying order. Due to the buffer polarization layer 4213, the display panel 4200 is thinner than the display panel 4100 and improves the transmittance of the light of the first polarized component and the absorptivity of the light of the second polarized component.

Therefore, the foregoing has to be considered as illustrative only, and it will be appreciated by those skilled in the art that various modifications and changes may be made in these exemplary embodiments. The scope of the invention is defined in the appended claims and their equivalents. Accordingly, all suitable modifications and equivalents may fall within the scope of the invention.

1. A display panel comprising:
a substrate;
a first electrode layer and a second electrode layer configured to face with each other in the substrate;
a light emitting layer configured to be interposed between the first electrode layer and the second electrode layer, and emit light based on voltage applied to the first electrode layer and the second electrode layer;
a polarization layer comprising a linear lattice configured to transmit a first polarized component of the light emitted from the light emitting layer, and reflect a second polarized component of the emitted light;
a phase shift layer configured to shift a phase of the light of the second polarized component reflected from the polarization layer, and output the light of the first polarized component by shifting a phase of the light reflected from at least one of the first electrode layer and the second electrode layer;
an absorption layer configured to be provided at a side where the light of the first polarized component of the polarization layer exits, transmit the light of the first polarized component from an outside, and absorb the light of the second polarized component from the outside; and
a buffer layer configured to be provided at a side where the light of the first polarized component of the polarization layer exits, and absorb the light of the second polarized component from the outside.

2. The display panel according to claim 1, wherein thickness of at least one of the absorption layer and the buffer layer has a value so that transmittance of the light of the first polarized component exiting to an outside can be equal to or higher than a first lower limit value, and absorptivity of the light of the second polarized component receiving from an outside can be equal to or higher than a second lower limit value.

3. The display panel according to claim 1, wherein thickness of the absorption layer is a value within a first range corresponding to a first lower limit value or higher of transmittance of the light, and thickness of the buffer layer is a value within a second range corresponding to a second lower limit value or higher of absorptivity of the light.

4. The display panel according to claim 1, wherein the buffer layer is interposed between the absorption layer and the polarization layer.

5. The display panel according to claim 1, wherein the buffer layer is interposed between the substrate and the polarization layer.

6. The display panel according to claim 1, wherein the buffer layer is stacked on the absorption layer.

7. The display panel according to claim 1, wherein the polarization layer comprises a plurality of linear lattices arranged in a lattice form to transmit the light of the first polarized component.

8. The display panel according to claim 7, wherein at least one of the absorption layer and the buffer layer is arranged in each of the plurality of linear lattices.

9. A display device comprising:
a signal receiver configured to receive an image signal;
a signal processor configured to process the image signal received in the signal receiver; and
a display panel configured to display the image signal processed by the signal processor,
the display panel comprising:
a substrate;
a first electrode layer and a second electrode layer configured to face with each other in the substrate;
a light emitting layer configured to be interposed between the first electrode layer and the second electrode layer, and emit light based on voltage applied to the first electrode layer and the second electrode layer;
a polarization layer comprising a linear lattice configured to transmit a first polarized component of the light emitted from the light emitting layer, and reflect a second polarized component of the emitted light;
a phase shift layer configured to shift a phase of the light of the second polarized component reflected from the polarization layer, and output the light of the first polarized component by shifting a phase of the light reflected from at least one of the first electrode layer and the second electrode layer;
an absorption layer configured to be provided at a side where the light of the first polarized component of the polarization layer exits, transmit the light of the first polarized component from an outside, and absorb the light of the second polarized component from the outside; and
a buffer layer configured to be provided at a side where the light of the first polarized component of the polarization layer exits, and absorb the light of the second polarized component from the outside.

10. The display device according to claim 9, wherein thickness of at least one of the absorption layer and the buffer layer has a value so that transmittance of the light of the first polarized component exiting to an outside can be equal to or higher than a first lower limit value, and absorptivity of the light of the second polarized component receiving from an outside can be equal to or higher than a second lower limit value.

11. The display device according to claim 9, wherein thickness of the absorption layer is a value within a first range corresponding to a first lower limit value or higher of transmittance of the light, and thickness of the buffer layer is a value within a second range corresponding to a second lower limit value or higher of absorptivity of the light.

12. The display device according to claim 9, wherein the buffer layer is interposed between the absorption layer and the polarization layer.

13. The display device according to claim 9, wherein the buffer layer is interposed between the substrate and the polarization layer.

14. The display device according to claim 9, wherein the buffer layer is stacked on the absorption layer.

15. The display device according to claim 9, wherein the polarization layer comprises a plurality of linear lattices arranged in a lattice form to transmit the light of the first polarized component, and at least one of the absorption layer and the buffer layer is arranged in each of the plurality of linear lattices.
